(19) United States
(12) Patent Application Publication
(10) Pub. No.: US 2012/0057711 A1
(43) Pub. Date: Mar. 8, 2012

(54) NOISE SUPPRESSION DEVICE, NOISE SUPPRESSION METHOD, AND PROGRAM

(76) Inventors: Kenichi MAKINO, Kanagawa (JP); Toru Chinen, Kanagawa (JP)

(21) Appl. No.: 13/223,131

(22) Filed: Aug. 31, 2011

(30) Foreign Application Priority Data
Sep. 7, 2010 (JP) P2010-199512

(51) Int. Cl. H03G 3/20

(52) U.S. Cl. 381/57

(57) ABSTRACT

A noise suppression device includes a framing unit, a band dividing unit, a band power computing unit, a noise determining unit that determines whether or not each band is noise, a noise band power estimating unit, a noise suppression gain determining unit, a noise suppression unit that applies the noise suppression gains and obtains a band divided signal of which noise has been suppressed, a band synthesizing unit, and a framing synthesizing unit that synthesizes the frames of the framing signals; the noise suppression gain determining unit having an SNR computing unit that computes an SNR for each band, and a SNR smoothing unit that smoothes the SNR computed for each band; wherein the noise suppression gains for each band are determined based on the SNR of each band smoothed by the SNR smoothing unit; and wherein the SNR smoothing unit changes the smoothing coefficient.

### BACKGROUND

The present disclosure relates to a noise suppression device, noise suppression method, and program, and more specifically, it relates to a noise suppression device or the like that performs an estimation of a noise signal from an input signal and obtains an output signal which is the noise signal that has been selectively decreased.

Hitherto, electronic devices, such as communication devices such as those using VoIP (Voice over Internet Protocol), and cellular phones and IC recorders, which subject a human voice recorded with a microphone to AD (Analog to Digital) conversion, and transmits/records this as a digital signal, then plays, have come to be widely used. At the time of using such electronic devices, the sounds emitted from the ambient environment can mix in to the microphone, preventing the voice from being heard.

Now, in related art, with a cellular phone or the like, noise suppression technology has been used wherein an estimation of the noise signal is performed from the input signal, and the noise signal is selectively reduced. This type of noise suppression technology is disclosed in Yariv Ephraim and David Malarah, “Speech Enhancement Using a Minimum Mean Square Error Short-Time Spectral Amplitude Estimator”, IEEE Transactions on Acoustics, Speech, And Signal Processing, Vol. ASSP-32, No. 6, December 1994 pp 1109-1121, for example.

### SUMMARY

With the above-described noise suppression technology, an input signal is divided into multiple bands, and of each bandwidth a signal bandwidth power and an SNR is computed from the estimated noise bandwidth power is computed, this computed SNR is smoothed, and a noise suppression gain is determined based on the smoothed SNR. In this case, a smoothing coefficient α of a fixed value of 0.98 is recommended, but this does not follow a fast signal change. Consequently, error can occur to the noise suppression gain, and can result in sound quality deterioration such as the start of audio being distorted and so forth. On the other hand, if a small value is used for the smoothing coefficient α in order to speed up the following speed, a reaction called musical noise can occur wherein the sound is abrasive to hear, and the sound quality deteriorates.

It is an object of the present disclosure to improve the sound quality in the event of performing estimation of a noise signal from an input signal and selectively reducing the noise signal.

According to an embodiment of the present disclosure, a noise suppression device includes: a framing unit configured to divide an input signal into frames of a predetermined frame length, and frames; a band dividing unit configured to divide the framing signal obtained with the framing unit into a plurality of bands and obtain a band divided signal; a band power computing unit configured to obtain band power from each band divided signal obtained with the band dividing unit; a noise determining unit configured to determine whether or not each band is noise, based on features of the framing signal; a noise band power estimating unit configured to estimate the noise band power of various bands from the determination results of the noise determining unit and band power of each band divided signals obtained with the band power computing unit; a noise suppression gain determining unit configured to determine noise suppression gains for each band, based on the noise band power of each band estimated with the noise band power estimating units and the band power of each band divided signals obtained with the band power computing unit; a noise suppression unit configured to apply the noise suppression gains of each band determined with the noise suppression gain determining unit to each band divided signals obtained with the band dividing unit, and obtain a band divided signal of which noise has been suppressed; a band synthesizing unit configured to synthesize the bands of each band divided signals obtained with the noise suppression unit, and obtain a framing signal of which noise has been suppressed; and a framing synthesizing unit configured to synthesize the frames of the framing signals of each frames obtained with the band synthesizing unit and obtain an output signal of which noise has been suppressed; the noise suppression gain determining unit having an SNR computing unit that computes an SNR from band power of each band divided signals obtained with the band power computing unit and the noise band power of each band estimated with the noise band power estimating unit, for each band, and a SNR smoothing unit configured to smooth the SNR computed with the SNR computing unit, for each band; wherein the noise suppression gains for each band are determined based on the SNR of each band smoothed by the SNR smoothing unit; and wherein the SNR smoothing unit changes the smoothing coefficient based on the determining results of the noise determining unit and frequency bands.

According to the present disclosure, the input signal is divided into frames of predetermined lengths by the framing unit. The framing signal is then divided into multiple bands by the band dividing unit and a band division signal is obtained. For example, with the band dividing unit herein, the framing signal is subjected to fast Fourier transform and caused to be a frequency region signal, and is divided into multiple bands.

With the band power computing unit, band power is obtained from each band division signal obtained with the band dividing unit. In this case, for example, a power spectrum is computed from a complex spectrum obtained with the Fourier transform, and the maximum value or average value or the like of the band of a power spectrum becomes a representative value, i.e. the band power.

With the noise determining unit, the band division signals of each band is determined to be noise or not, based on the features of the framing signal. For example, the various bands are sequentially set as determining bands, the band power of the current frame and past frame of the band division signal of the determining band herein are compared, and in the event that variances of the band power are within a threshold, the determining band herein is determined to be noise. This determination is based on the assumption that noise power is constant between frames, and conversely that signals having wide power variances are not noise.

Also, for example, each band is determined to be noise or not, based on a histogram of the zero cross width of a framing signal. For example, when not noise, similar waveforms are repeated, whereby a predetermined zero cross width frequency increases. Therefore, each band can be determined to be noise or not, based on the histogram of the zero cross width.

Also, for example, the first determination of whether each band is noise or not is performed, based on the histogram of the zero cross width of the framing signal. With this first determination, when each band is determined to be noise, the next determination is performed. In the next determination, when each band is sequentially a determining band, the current frame and past frame of the band division signal of the determining band herein are compared, and variances of the band power are within a threshold, that determining band is determined to be noise. With such a two-stage determination, precision of noise determination can be improved.

There are cases wherein determining only by monitoring the state of the band division signal in order to determine whether or not each band is noise is insufficient. For example, in the case of detecting stationarity of the band power and determining this as noise, particularly in a case that the bandwidth of the band division is wide, a tonal signal and noise are indistinguishable. Now, by performing determination as to whether or not the overall frame is noise, and by combining this with determining of the overall band, final noise determining precision can be improved.

With the noise band power estimating unit, from the band power of the various band division signals obtained with the band power computing unit and the determination results of the noise determining unit, the noise band power of each band is estimated. For example, estimation of the noise band power of a band determined to be noise is performed by weighted addition of the estimated value of the band power of the noise of a previous frame and the band power of the band division signal, and updating this.

With the noise suppression gain determining unit, the noise suppression gain for each band is determined, based on the band power of the noise of each band estimated with the noise band power estimating unit and the band power of the various band division signals obtained with the band power computing unit. In this case, the noise suppression gain determining unit is made up of an SNR computing unit that computes an SNR from the band power of the various band division signals obtained with the band power computing unit and the noise band power of each band estimated with the noise band power estimating unit, for each band, and an SNR smoothing unit that smoothes the SNR computed with the SNR computing unit, for each band.

With the noise suppression gain determining unit, a noise suppression gain for each band is determined, based on the SNR of each band smoothed with the SNR smoothing unit. In this case, the smoothing coefficient is modified based on the determining results of the noise determining unit and the frequency bands.

For example, with the noise suppression gain determining unit, the ratio of the band power of a current frame signal and the estimated noise band power are set as a first SNR, the ratio of an amount wherein the band power of the immediately preceding frame signal and the noise suppression gain are multiplied, and the estimated noise band power of the immediately preceding frame, are set as a second SNR, and for each frame, a noise suppression gain using the first SNR and the second SNR is determined.

Note that with the noise suppression gain determining unit, the noise suppression gain for each band is determined together with the SNR of each band smoothed with the SNR smoothing unit, based on the SNR computed with the SNR computing unit.

With the noise suppression unit, a noise suppression gain of each band determined with the noise suppression gain determining unit is applied to each band division signal obtained with the band dividing unit, and band division signals of which noise has been suppressed are obtained. Also, with the band synthesizing unit, framing signals of which the various band division signals obtained with the noise suppression unit are subjected to band synthesizing and noise suppression are obtained, and with a frame synthesizing unit, the framing signals for each frame obtained with the band synthesizing unit is subjected to frame synthesizing, and an output signal of which noise has been suppressed is obtained.

Thus, according to the present disclosure, for each band, noise suppression gain is determined based on the smoothing SNR, but the smoothing coefficient thereof is modified based on the determining result of the noise determining unit and the band. For example, in the case of determining as non-noise in each frame and each band, the smoothing coefficient (a) is changed towards a smaller value, and in the case of determining noise, the smoothing coefficient (a) is changed towards a larger value. Thus, following of a smoothing SNR in locations having wide signal time variances can be improved, and unnecessary change of the smoothing SNR in locations having few signal time variances can be avoided. Therefore, precision of the noise suppression gain for each band can be improved, and deterioration of sound quality can be suppressed to a small amount.

According to the present disclosure, for example, when the noise suppression gain determined with the noise suppression gain determining unit becomes smaller than a lower limit value set beforehand, a noise suppression gain correcting unit that corrects the noise suppression value to the lower limit value herein is further provided, and the noise suppression gain corrected with the noise suppression gain correcting unit is used.

In this case, the lower limit value is set separately for each band. For example, in the case that the non-noise signal is a voiced sound, for a band having a high probability of including a voiced sound signal, the lower limit value of the noise suppression gain is set to a higher value. In the case that the noise suppression gain determining with the noise suppression gain determining unit is lower than the lower limit value, this is replaced by the lower limit value. Thus, even if there is any error in noise suppression gain determining with the noise suppression gain determining unit, sound quality deterioration being heard is reduced.

According to an embodiment of the present disclosure, a noise suppression device includes: multiple framing units configured to divide input signals of multiple channels into frames of a predetermined frame lengths, respectively, and frame; multiple band dividing units configured to divide the framing signals obtained with the plurality of framing units into multiple bands, respectively, and obtain band divided signals; multiple band power computing units configured to obtain band power from each band division signals obtained with the plurality of band dividing units, respectively; a noise determining unit configured to determines whether or not each band is noise, based on features of the framing signals of the plurality of channels; multiple noise band power estimating units configured to estimate the noise band power of various bands from the determination results of the noise determining unit and band power of each band divided signals obtained with the plurality of band power computing units; multiple noise suppression gain determining units configured to determine noise suppression gains for each band, based on the noise band power of each band estimated with the plurality of noise band power estimating units and the band power of each band divided signals obtained with the plurality of band power computing units; multiple noise suppression units configured to apply the noise suppression gains of each band determined with the plurality of noise suppression gain determining units to each band divided signals obtained with the plurality of band dividing units, and obtains band divided signals of which noise have been suppressed, respectively; multiple band synthesizing units configured to synthesize the bands of each band divided signals obtained with the plurality of noise suppression units, and obtain framing signals of which noise have been suppressed, respectively; and multiple framing synthesizing units configured to synthesize the frames of the framing signals of each frames obtained with the plurality of band synthesizing units and obtain output signals of which noise have been suppressed, respectively; the noise suppression gain determining unit having an SNR computing unit configured to compute an SNR from band power of each band divided signals obtained with the band power computing unit and the noise band power of each band estimated with the noise band power estimating unit, for each band, and a SNR smoothing unit configured to smooth the SNR computed with the SNR computing unit, for each band; wherein the noise suppression gains for each band are determined based on the SNR of each band smoothed by the SNR smoothing unit; and wherein the SNR smoothing unit changes the smoothing coefficient based on the determining results of the noise determining unit and frequency bands.

According to the present disclosure, noise suppression gains are determined for each channel with the noise determining unit, and noise suppression processing is performed. Based on features of the framing signals in multiple channels, each band is determined to be noise or not. For example, the various bands are sequentially determining bands, and determination of noise or not is made for each channel for the determining band, and when all of the channels are determined to be noise, the determining band is determined to be noise. In each channel, in the event of determining the noise suppression gain for each band for each frame, the determining results of the noise determining unit are used in common.

Thus, according to the present disclosure, unintended amplitude difference is suppressed from occurring to the noise suppression gain of the multiple channels by noise band power estimating error in the multiple channels (e.g., the left and right channels in the case of a stereo signal), and deterioration in localization due to inconsistency in the left and right channels can be avoided.

According to the present disclosure, deterioration of sound quality in the event of estimating the noise signal from the input signal and selectively reducing the noise signal can be suppressed to a small amount.

### BRIEF DESCRIPTION OF THE DRAWINGS

FIG. 1 is a block diagram illustrating a configuration example of a noise suppression device according to a first embodiment of the present disclosure;

FIG. 2 is a diagram to describe calculation operations with a zero cross width calculating unit of a voiced sound detecting unit;

FIGS. 3A and 3B are diagrams illustrating an example of a signal waveform (amplitude of various samples) and a zero cross width histogram in the case that a framed signal is audio (non-noise);

FIGS. 4A and 4B are diagrams illustrating an example of a signal waveform (amplitude of various samples) and a zero cross width histogram in the case that a framed signal is audio (noise);

FIG. 5 is a flowchart to describe procedures for determining processing of a noise/non-noise determining unit;

FIG. 6 is a diagram illustrating a transition example of a weighted coefficient α(k,b) computed with an α computing unit;

FIG. 7 is a block diagram illustrating a configuration example of a noise suppression device according to a second embodiment of the present disclosure;

FIG. 8 is a block diagram illustrating a configuration example of a noise suppression gain generating unit that configures a noise suppression device;

FIG. 9 is a flowchart to describe procedures for determining processing of a noise/non-noise determining unit; and

FIG. 10 is a diagram illustrating a configuration example of a computer device that performs noise suppression processing using software.

### DETAILED DESCRIPTION OF EMBODIMENTS

Embodiments of the present disclosure (hereafter called “embodiments”) will be described below. Note that the description will be made in the following order.

### 1. First Embodiment

### 2. Second Embodiment

### 3. Modification

### 1. First Embodiment

### Noise Suppression Device

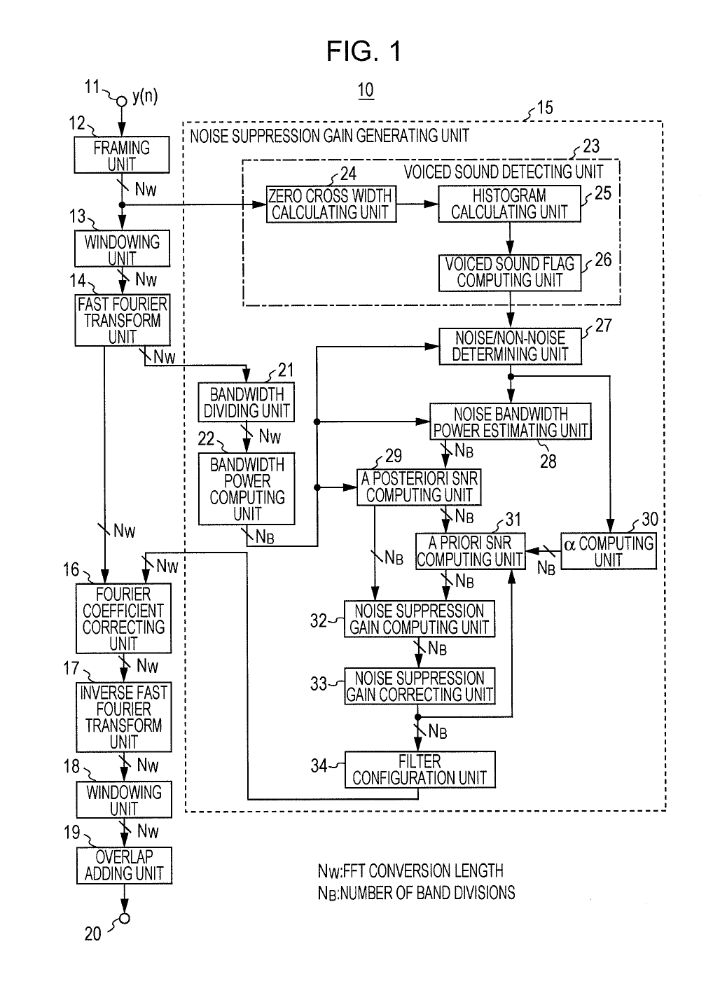

FIG. 1 shows a configuration example of a noise suppression device 10 according to a first embodiment. The noise suppression device 10 has a signal input terminal 11, framing unit 12, windowing unit 13, Fast Fourier Transform unit 14, and noise suppression gain generating unit 15. Also, the noise suppression device 10 has a Fourier coefficient correcting unit 16, Inverse Fast Fourier Transform unit 17, windowing unit 18, overlap adding unit 19, and signal output terminal 20.

The signal input terminal 11 is a terminal to supply the input signal y(n). The input signal y(n) is a digital signal of which a standardized frequency is fs. The framing unit 12 divides the input signal y(n) supplied to the signal input terminal 11 into predetermined frame lengths, for example, a frame length of Nf sample frames, and frames these, in order to perform processing for each frame. For example, a n′th sample of a signal of a k′th frame is denoted as yf(k,n). The framing processing of the framing unit 12 may allow overlapping of adjacent frames.

The windowing unit 13 performs windowing to a framing signal yf(k,n) with an analyzing window wana(n). The windowing unit 13 uses an analyzing window wana(n) that is defined by Expression (1) below, for example. Nw is the window length.

$${w}_{ana} ( n ) = \sqrt{0.5 - 0.5 * cos ( \frac{2 π n}{{N}_{w}} )} \qquad ( 1 )$$

The Fast Fourier Transform unit 14 performs Fast Fourier Transform (FFT: Fast Fourier transform) processing on the framing signal yf(k,n) subjected to windowing at the windowing unit 13, and transforms a time region signal into a frequency region signal. The noise suppression gain generating unit 15 generates the noise suppression gain corresponding to the various Fourier coefficients, based on the framing signal yf(k,n) obtained with the framing processing and the various Fourier coefficients (various frequency spectrums) obtained with the Fast Fourier Transform processing. The noise suppression gains corresponding to the various Fourier coefficients make up the filter on the frequency axis. Details of the noise suppression gain generating unit 15 herein will be described later.

The Fourier coefficient correcting unit 16 performs coefficient correction by taking the product of the various Fourier coefficients obtained with the Fast Fourier Transform processing and the noise suppression gains corresponding to the various Fourier coefficients generated with the noise suppression gain generating unit 15. That is to say, the Fourier coefficient correcting unit 16 performs filter calculations for suppressing the noise on the frequency axis.

The Inverse Fast Fourier Transform unit 17 performs Inverse Fast Fourier Transform (IFFT: Inverse Fast Fourier transform) processing as to the various Fourier coefficients subjected to coefficient correction. The Inverse Fast Fourier Transform unit 17 performs inverse processing as to the above-described Fast Fourier Transform unit 14, and transforms a frequency region signal into a time region signal.

The windowing unit 18 performs windowing with a synthesis window wsyn(n) on framing signals subjected to noise suppression obtained with the Inverse Fast Fourier Transform unit 17. The windowing unit 18 uses a synthesis window wsyn(n) which is defined by Expression (2) below, for example.

$${w}_{sys} ( n ) = \sqrt{0.5 - 0.5 * cos ( \frac{2 π n}{{N}_{w}} )} \qquad ( 2 )$$

Note that the forms of the analyzing window wana(n) with the windowing unit 13 and the synthesis window wsyn(n) with the windowing unit 18 may be arbitrary. However, for an analyzing/synthesis series system, using that which satisfies complete reconfiguration conditions is desirable.

The overlap adding unit 19 performs layering of the frame border portions of the framing signals of each frame subjected to windowing with the windowing unit 18, and obtains output signals of which noise has been suppressed. The signal output terminal 20 outputs the output signals obtained with the overlap adding unit 19.

Operations of the noise suppression device 10 will be briefly described. An input signal y(n) is supplied to the signal input terminal 11, and the input signal y(n) herein is supplied to the framing unit 12. With this framing unit 12, the input signal y(n) is subjected to framing in order to perform processing for each frame. That is to say, with the framing unit 12, the input signal y(n) is divided into predetermined frame lengths, for example, frames having a frame length of Nf samples. The framing signal yf(k,n) for each frame is sequentially supplied to the windowing unit 13.

With the windowing unit 13, windowing with the analyzing window wana(n) is performed on the framing signal f(k,n) in order to obtain the Fourier coefficient stabilized with the Fast Fourier Transform unit 14 described later. The framing signal yf(k,n) thus windowed is supplied to the Fast Fourier Transform unit 14. With the Fast Fourier Transform unit 14 herein, Fast Fourier Transform processing is performed as to the windowed framing signal yf(k,n), and a time region signal is transformed to a frequency region signal. The various Fourier coefficients (various frequency spectrums) obtained with the Fast Fourier Transform processing are supplied to the Fourier coefficient correcting unit 16.

The framing signal yf(k,n) for each frame obtained with the framing unit 12 is supplied to the noise suppression gain generating unit 15. Also, the various Fourier coefficients for each frame obtained with the Fast Fourier Transform unit 14 are supplied to the noise suppression gain generating unit 15. With the noise suppression gain generating unit 15, a noise suppression gain corresponding to each Fourier coefficient is generated for each frame, based on the framing signal yf(k,n) and each Fourier coefficient. The noise suppression gains corresponding to the various Fourier coefficients are supplied to the Fourier coefficient correcting unit 16.

With the Fourier coefficient correcting unit 16, for each frame, the product is taken of the various Fourier coefficients obtained by Fast Fourier Transform processing with the Fast Fourier Transform unit 14 and the noise suppression gain corresponding to the various Fourier coefficients generated with the noise suppression gain generating unit 15, and coefficient correction is performed. That is to say, with the Fourier coefficient correcting unit 16, filter calculations are performed on the frequency axis for suppressing the noise. The various Fourier coefficients subjected to coefficient correction are supplied to the Inverse Fast Fourier Transform unit 17.

With the Inverse Fast Fourier Transform unit 17, inverse Fast Fourier Transform processing is performed for each frame as to the various Fourier coefficients subjected to coefficient correction, and the frequency region signals are transformed to time region signals. The framing signals obtained with the Inverse Fast Fourier Transform unit 17 are supplied to the windowing unit 18. With the windowing unit 18, windowing with synthesis window wsyn(n) is performed as to the framing signals subjected to noise suppression which are obtained with the Inverse Fast Fourier Transform unit 17 for each frame.

The framing signals of each frame windowed with the windowing unit 18 are supplied to the overlap adding unit 19. With the overlap adding unit 19, layering of the frame border portions of the framing signals for each frame is performed, and an output signal for which noise has been suppressed is obtained. The output signal herein is output to the signal output terminal 20.

Noise Suppression Gain Generating Unit

Details of the noise suppression gain generating unit 15 will be described. The noise suppression gain generating unit 15 basically uses the noise suppression technology disclosed in the above-described Non-Patent Document 1 and so forth to generate the noise suppression gain. First, an overview of this noise suppression technology will be described below.

With the noise suppression technology here, when the input band signal of a b′th band of a k′th frame is Y(k,b), as shown in Expression (3) below, the noise suppression gain G(k,b) is used, and a band signal X(k,b) having noise suppressed is obtained. The noise suppression gain G(k,b) is calculated from the a priori SNR “ξ(k,b)” and a posteriori SNR “γ(k,b)” are calculated.

X(k,b)=G(k,b)Y(k,b) (3)

The a posteriori SNR “γ(k,b)” is calculated with Expression (4) below, when the band power of the input signal is B(k,b) and the estimated band power of the noise is D(k,b).

γ(k,b)=B(k,b)/D(k,b) (4)

The a priori SNR “ξ(k,b)” uses a weighted coefficient (smoothing coefficient) α and is calculated with Expression (5) below.

ξ(k,b)=αG²(k−1,b)γ(k−1,b)+(1−α)P[γ(k,b)−1] (5)

Now, P[.] is an operator that is defined as in Expression (6) below.

$$P [ x ] = \{ \begin{matrix}x & if x \leq 0 \\ 0 & otherwise\end{matrix} \qquad ( 6 )$$

The noise suppression gain G(k,b) uses an a priori SNR “ξ(k,b)” and a posteriori SNR “γ(k,b)” to calculated as in Expression (7) below. In(x) is a first type of modified Bessel function.

$$G ( k , b ) = \frac{\sqrt{π}}{2} \frac{\sqrt{v ( k , b )}}{γ ( k , b )} exp ( - \frac{v ( k , b )}{2} ) [ ( 1 + v ( k , b ) ) {I}_{0} ( \frac{v ( k , b )}{2} ) + v ( k , b ) {I}_{1} ( \frac{v ( k , b )}{2} ) ] \\ [ where v ( k , b ) = \frac{ξ ( k , b )}{1 + ξ ( k , b )} γ ( k , b ) ] \qquad ( 7 )$$

Since the noise suppression gain is calculated from the estimated values of the a priori SNR and a posteriori SNR, estimation precision directly influences the appropriateness of the noise suppression. Of these, the noise band power estimating value D(k,b) influences all of the SNR estimated values, whereby improvement to the estimation precision becomes an important problem in aiming to improve functionality of the overall device.

Even in a case where there is assumed to be no estimation error to the noise band power, with the calculation method of the above-described SNR (see Expression (5)), the non-patent document 1 recommends handling a fixed value of α=0.98, and the estimation does not follow a fast signal change. Consequently, an estimation error of the noise suppression gain G(k,b) occurs, and becomes the cause for sound quality deterioration such as the start of audio being distorted. On the other hand, if a small value is used for a in order to make the following speed be faster, there is a problem wherein this time a reaction occurs of an abrasive sound to hear, called musical noise, and the sound quality deteriorates.

The noise suppression gain generating unit 15 basically uses a noise suppression technology disclosed in the above-described non-patent document 1, for example. However, by estimating the noise band power with good precision while performing appropriate coefficient modification according to the state of the signal, generating optimal noise suppression gain G(k,b) can be performed.

The noise suppression gain generating unit 15 has a band dividing unit 21, band power computing unit 22, voiced sound detecting unit 23, noise/non-noise determining unit 27, and noise band power estimating unit 28. Also, the noise suppression gain generating unit 15 has an a posteriori SNR computing unit 29, a computing unit 30, a priori SNR computing unit 31, noise suppression gain computing unit 32, noise suppression gain correcting unit 33, and filter configuration unit 34.

The band dividing unit 21 divides the various frequency spectrums (various Fourier coefficients) obtained by Fast Fourier transform processing with the fast Fourier transform unit 14, into 25 frequency bands, for example. Table 1 shows an example of band division. The band numbers are numbers appended to identify each band. The various frequency bands are based on knowledge obtained from auditory psychology research indicating that with human auditory systems, the higher a band, the more that perception resolution deteriorates.

TABLE 1

| Band Number | Frequency Range |
|---|---|
| 0 | 0-125 Hz |
| 1 | 125-250 Hz |
| 2 | 250-375 Hz |
| 3 | 376-563 Hz |
| 4 | 563-750 Hz |
| 5 | 750-938 Hz |
| 6 | 938-1125 Hz |
| 7 | 1125-1313 Hz |
| 8 | 1313-1563 Hz |
| 9 | 1563-1813 Hz |
| 10 | 1813-2063 Hz |
| 11 | 2063-2313 Hz |
| 12 | 2313-2563 Hz |
| 13 | 2563-2813 Hz |
| 14 | 2813-3063 Hz |
| 15 | 3063-3375 Hz |
| 16 | 3375-3688 Hz |
| 17 | 3688-4370 Hz |
| 18 | 4370-5235 Hz |
| 19 | 5235-6375 Hz |
| 20 | 6375-7658 Hz |
| 21 | 7658-9354 Hz |
| 22 | 9354-11775 Hz |
| 23 | 11775-15513 Hz |
| 24 | 15513-22050 Hz |

The band power computing unit 22 computes band power B(k,b) from the frequency spectrum of each band divided by the band dividing unit 21. Now, (k,b) shows a k′th frame and b′th band. As a method to compute the band power B(k,b), the band power computing unit 22 may use a method that computes the power spectrum from the various frequency spectrums, obtains an maximum value within the frequency ranges, and uses this maximum value as a representative value B(k,b). Note that, as for a method to calculate the band power B(k,b), the band power computing unit 22 may use a method that computes the power spectrum from the various frequency spectrums, obtains an average value within the frequency ranges, and uses this average value as a representative value B(k,b).

The voiced sound detecting unit 23 outputs a voiced sound flag Fv(k) indicating whether or not a voiced sound is included for each frame, based on the framing signal yf(k,n) obtained with the framing unit 12. The voiced sound detecting unit 23 has a zero cross width calculating unit 24, histogram calculating unit 25, and voiced sound flag computing unit 26.

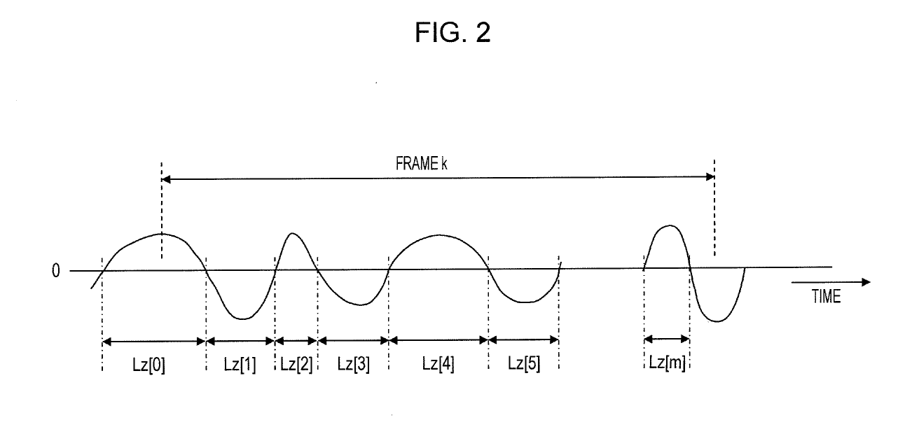

The zero cross width calculating unit 24 detects, as zero cross points, locations where the sign between framed consecutive samples reverse from positive to negative, or negative to positive, for example, or locations where a sample exists that has a value called 0 between samples having the opposite signs. Also, the zero cross width calculating unit 24 calculates the number of samples between adjacent zero cross points and records as zero cross widths to show as Lz(0), Lz(1), . . . , Lz(m), as shown in FIG. 2.

The histogram calculating unit 25 receives the zero cross width Lz(p) from the zero cross width calculating unit 24, and researches the distribution within the frame. For example, in the case of taking the statistics of 20 regions every 10 samples, the histogram calculating unit 25 sets the initial value as Hz(q)=0(0≦q<20). The histogram calculating unit 25 then obtains a histogram Hz(q) as in Expression (8) below.

$$\{ \begin{matrix}{H}_{z} ( q ) = {H}_{z} ( q ) + 1 & if q < 19 , q * 10 \leq {L}_{z} ( p ) < ( q + 1 ) * 10 \\ {H}_{z} ( 19 ) = {H}_{z} ( 19 ) + 1 & otherwise\end{matrix} \qquad ( 8 )$$

The voiced sound flag computing unit 26 obtains an index (hierarchy) qpeak where the frequency Hz(q) obtained with the histogram calculating unit 25 is the maximum value. The voiced sound flag calculating unit 26 then compares the frequency Hz(q) of the index qpeak to a threshold value Th(q) of the index qpeak, and sets a voiced sound flag Fv(k) as shown in Expression (9) below. Now, the various indexes show various zero cross width ranges.

$${F}_{v} ( k ) = \{ \begin{matrix}1 & if {H}_{z} ( {q}_{peak} ) > {T}_{h} ( {q}_{peak} ) \\ 0 & otherwise\end{matrix} \qquad ( 9 )$$

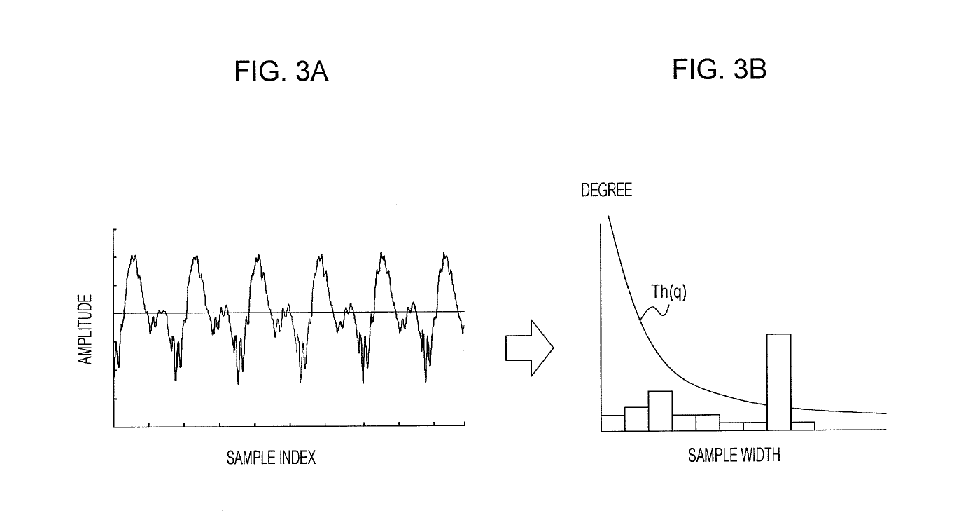

FIGS. 3A and 3B show an example of a signal waveform (amplitude of samples) and a histogram of the zero cross width in the case that the framing signal yf(k,n) is a voiced sound (non-noise). In the case of voiced sound (non-noise), a similar waveform is repeated, and the frequency of the predetermined zero cross width range increases. Therefore, Hz(q)>Th(q) holds, and the voiced sound flag Fv(k) is set to Fv(k)=1. Now, the threshold Th(q) is set for each zero cross width range (index), such that the smaller the zero cross width of the zero cross range is, the greater the value of the corresponding Th(q) is.

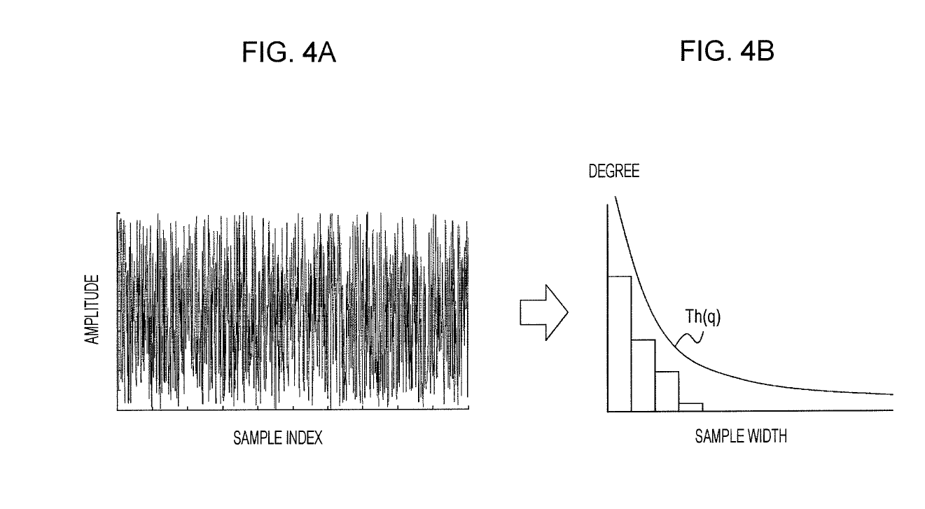

On the other hand, FIGS. 4A and 4B show an example of a signal waveform (amplitude of samples) and a histogram of the zero cross width in the case that the framing signal yf(k,n) is noise. In the case of noise, the frequency of the zero cross width range with a small zero cross width increases. Therefore, Hz(q) Th(q) holds, and the voiced sound flag Fv(k) is set to Fv(k)=0.

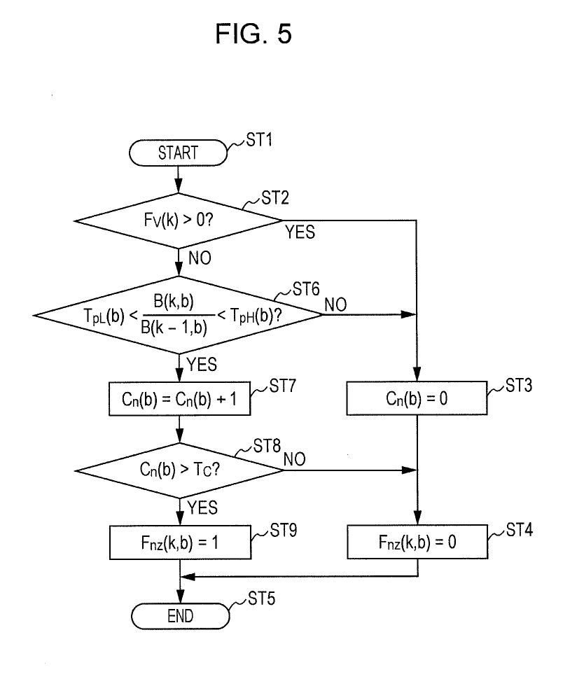

The noise/non-noise determining unit 27 uses the voiced sound flag Fv(k) obtained with the voiced sound detecting unit 23 and the band power B(k,b) of each band computed with the band power computing unit 22, and sets a noise band flag Fnz(k,b) of each band, for each frame. The noise/non-noise determining unit 27 executes the determining processing shown in the flowchart in FIG. 5 of each band for each frame.

The noise/non-noise determining unit 27 starts the determining processing in step ST1, and performs system initialization. With this initialization, the noise/non-noise determining unit 27 initializes the noise candidate frame continuous counter Cn(b) at Cn(b)=0.

Next, the noise/non-noise determining unit 27 moves to the processing in step ST2. In step ST2 herein, the noise/non-noise determining unit 27 determines whether or not the voiced sound flag Fv(k) is greater than 0, i.e., whether or not FV(k)=1. When Fv(k)=1, i.e., when the current frame k is a voiced sound, the noise/non-noise determining unit 27 clears the noise candidate frame continuous counter Cn(b) in step ST3 and sets this to Cn(b)=0. The noise/non-noise determining unit 27 then determines that the current band b is not noise, and in step ST4 sets the noise band flag Fnz(k,b) to Fnz(k,b)=0, and thereafter ends the determining processing in step ST5.

When Fv(k)=0 in step ST2, i.e., when the current frame k is not a voiced sound, the noise/non-noise determining unit 27 moves to the processing in step ST6. In step ST6, the noise/non-noise determining unit 27 obtains the power ratio of the band power B(k,b) of the current frame k and the band power B(k−1,b) of the immediately preceding frame k−1. The noise/non-noise determining unit 27 then determines in step ST 6 whether or not the power ratio is contained between a low level side threshold TpL(b) and a high level side threshold TpH(b).

When the power ratio is contained within the threshold values, the noise/non-noise determining unit 27 sets the current band b as a noise candidate, and when the power ratio is not contained within the threshold values, determines that the current band b is not noise. This determination is based on the assumption that noise signal power is fixed, and conversely that a signal having wide power variances is not noise.

When the power ratio is not contained within the threshold values, i.e., when determining that the current band b is not noise, the noise/non-noise determining unit 27 clears the noise candidate frame continuous counter Cn(b) in step ST3, and sets this to Cn(b)=0. The noise/non-noise determining unit 27 then sets Fnz(k,b)=0 in step ST4, and thereafter ends the determining processing in step ST5.

On the other hand, when the power ratio is contained within the threshold values, i.e., when the current band b is set as a noise candidate, the noise/non-noise determining unit 27 moves to the processing in step ST7. In step ST7, the noise/non-noise determining unit 27 increases the count of the noise candidate frame continuous counter Cn(b) by 1.

The noise/non-noise determining unit 27 then determines in step ST 8 whether or not the noise candidate frame continuous counter Cn(b) has exceeded a threshold value Tc. When Cn(b)>Tc does not hold, the noise/non-noise determining unit 27 determines that the current band b is not noise, and sets Fnz(k,b)=0 in step ST4, and thereafter ends the determining processing in step ST5.

On the other hand, when Cn(b)>Tc, the noise/non-noise determining unit 27 moves to the processing in step ST9. In step ST9, the noise/non-noise determining unit 27 determines that the current band b is noise, and sets the noise band flag Fnz(k,b) to Fnz(k,b)=1, and thereafter ends the determining processing in step ST5.

With the determining processing in the above-described flowchart in FIG. 5, the voiced sound flag Fv(k) obtained with the voiced sound detecting unit 23 performs noise/non-noise determining once for the entire frame, which by combining this with the determination of each band becomes the final determination result. This is because there may be cases wherein determination performed only by monitoring the signal state of each band is insufficient. For example, in the case of detecting the stationarity of the band power and determining this as noise, in particular with a case where the width of the bandwidth of band division is wide, a tonal signal and noise are not distinguished. Accordingly, by performing the determining processing in the flowchart in FIG. 5, noise determining precision of each band can be improved.

Returning to FIG. 1, the noise band power estimating unit 28 estimates the noise band power estimated value D(k,b) of each band, for each frame. The noise band power estimating unit 28 performs updates to the noise band power estimated value D(k,b), only for bands where Fnz(k,b)=1, i.e., for noise bands, based on the noise band flags Fnz(k,b) set with the noise/non-noise determining unit 27.

As an example of the updating method of the noise band power estimating value D(k,b) with the noise band power estimating unit 28, for example, a method to use the band power B(k,b) and update using exponential weighting μnz, may be considered, as shown in Expression (10) below. It is favorable for the value of μnz to be set between approximately 0.9 and 1.0, the noise band power estimating value D(k,b) to follow the actual noise changes, and for there to be no acoustic unpleasantness.

D(k,b)=μ_{nz}D(k−1,b)+(1−μ_{nz})B(k,b) if F_{nz}(k,b)==1 (10)

The a posteriori SNR computing unit 29 uses the input signal band power B(k,b) and the estimated value D(k,b) of the noise band power, and computes the a posteriori SNR “y(k,b)” of each band for each frame, based on Expression (11) below. This Expression (11) is the same as the above-mentioned Expression (4). The a posteriori SNR computing unit 29 makes up the SNR computing unit.

γ(k,b)=B(k,b)/D(k,b) (11)

The a priori SNR computing unit 31 computes the a priori SNR “ξ(k,b)” of each band, for each frame, based on Expression (12) below. In this case, the a priori SNR computing unit 31 uses the a posteriori SNR “γ(k−1,b), γ(k,b)” of the current frame and immediately preceding frame, the noise suppression gain G′(k−1,b) of the immediately preceding frame, and the weighted coefficient α. Note that Expression (12) is the same as the above-mentioned Expression (5), except for the noise suppression gain G(k−1,b) changing to noise suppression gain G′(k−1,b) after correction by limiter processing.

ξ(k,b)=αG′²(k−1,b)γ(k−1,b)+(1−α)P[γ(k,b)−1] (12)

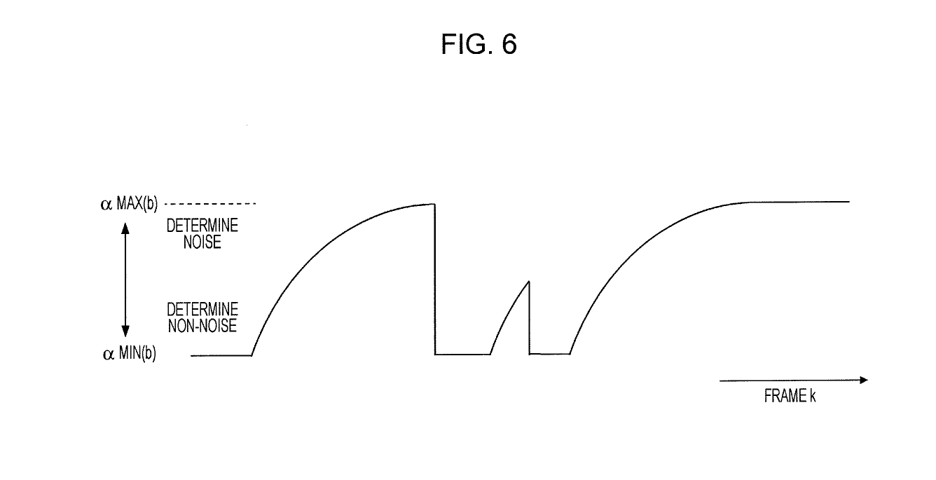

The α computing unit 30 computes the weighted coefficient α in the above-mentioned Expression (12), not as a fixed value, but as a weighted coefficient α(k,b) that varies with the frame and frequency band, based on Expression (13). αMAX(b) and αMIN(b) are the maximum value and minimum value, respectively, for the weighted coefficient α(k,b) set of each band. In the case of computing the weighted coefficient α(k,b) based on Expression (13), at band b that is determined to be noise, the weighted coefficient α(k,b) nears the maximum value αMAX(b), and at band b that is determined to be non-noise, the weighted coefficient α(k,b) nears the minimum value αMIN(b). FIG. 6 shows a transition example of the weighted coefficient α(k,b).

$$α ( k , b ) = \{ \begin{matrix}{μ}_{α} α ( k - 1 , b ) + ( 1 - {μ}_{α} ) {α}_{MAX} ( b ) & if {F}_{nz} ( k , b ) > 0 \\ {α}_{MIN} ( b ) & otherwise\end{matrix} \qquad ( 13 )$$

If the α in the above-mentioned Expression (12) is rewritten in the form using the above-mentioned α(k,b), this becomes as in Expression (14) below.

ξ(k,b)=α(k−1,b)G′²(k−1,b)γ(k−1,b)+(1−α(k,b))P[γ(k,b)−1] (14)

The a priori SNR computing unit 31 performs computation of the a priori SNR “ξ(k,b)”, based on the above-mentioned Expression (14). With the structure of the computations of the above-described weighted coefficient α(k,b), the a priori SNR “ξ(k,b)” is calculated so that following is fast as to non-noise that generally changes widely such as audio, and following is slow as to noise of which stationarity is assumed. The a priori SNR computing unit 31 makes up an SNR smoothing unit.

The noise suppression gain computing unit 32 computes the noise suppression gain G(k,b) of each band, for each frame, from the a posteriori SNR “γ(k,b)” computed with the a posteriori SNR computing unit 29 and the a priori SNR “ξ(k,b)” computed with the a priori SNR computing unit 31, based on Expression (15) below. Note that Expression (15) herein is the same as the above-mentioned Expression (7).

$$G ( k , b ) = \frac{\sqrt{π}}{2} \frac{\sqrt{v ( k , b )}}{γ ( k , b )} exp ( - \frac{v ( k , b )}{2} ) [ ( 1 + v ( k , b ) ) {I}_{0} ( \frac{v ( k , b )}{2} ) + v ( k , b ) {I}_{1} ( \frac{v ( k , b )}{2} ) ] \\ [ where v ( k , b ) = \frac{ξ ( k , b )}{1 + ξ ( k , b )} γ ( k , b ) ] \qquad ( 15 )$$

The noise suppression gain correcting unit 33 factors a limiter to the noise suppression gain G(k,b) computed with the noise suppression gain computing unit 32, based on a lower-limit value GMIN(b) of the noise suppression gain set beforehand of each band, and computes a corrected noise suppression gain G′(k,b). Expression (16) below shows the limiter processing at the noise suppression gain correcting unit 33.

$${G}^{′} ( k , b ) = \{ \begin{matrix}{G}_{MIN} ( b ) & if G ( k , b ) < {G}_{MIN} ( b ) \\ G ( k , b ) & otherwise\end{matrix} \qquad ( 16 )$$

The noise suppression gain correcting unit 33 is provided so that while the acoustic noise reduction amount is maximized, the noise suppression gain is prevented from becoming too small as a result of excessive estimating with the noise estimation. Now, the lower limit value GMIN(b) is set by band, based on the nature of the corresponding sound source and acoustic psychology. For example, in the case that the non-noise signal is audio, a band having a high probability that audio is included is set where the lower limit value of the noise suppression gain is a higher value. In the case that the noise suppression gain G(k,b) is lower than the lower limit value GMIN(b), this is replaced by the lower limit value GMIN(b). Thus, even if there if error in the noise suppression gain G(k,b), acoustic sound quality deterioration is decreased.

The filter configuration unit 34 computes a noise suppression gain corresponding to the various Fourier coefficients, for each frame, from the noise suppression gain G′(k,b) of each band for each frame corrected with the noise suppression gain correcting unit 33, and configures a filter on the frequency axis. The calculating method may be a simple method wherein the band division of the Fourier coefficient is subjected to inverse mapping with the band dividing unit 21 and that which is obtained is used without change, or may be a method where that this is obtained with the method described above is further smoothed on the frequency axis so the gain does not become non-continuous on the frequency axis.

The operations of the noise suppression gain generating unit 15 will be briefly described. The various frequency spectrums (various Fourier coefficients) obtained by fast Fourier transform processing with the fast Fourier transform unit 14 for each frame are supplied to the band dividing unit 21. With the band dividing unit 21, the various frequency spectrums are divided into 25 frequency bands, for example, for each frame (see Chart 1).

The frequency spectrums of each band obtained by band division with the band diving unit 21 are supplied to the band power computing unit 22, for each frame. With the band power computing unit 22, the band power B(k,b) for each band is computed, for each frame. For example, the power spectrum corresponding to each various frequency spectrum within the band b is computed, and the maximum value or average value thereof becomes the band power B(k,b).

Also, the framing signal yf(k,n) obtained with the framing unit 12 is supplied to the voiced sound detecting unit 23. With the voiced sound detecting unit 23, a voiced sound flag Fv(k) showing whether or not a voiced sound is included in each frame, based on the framing signal yf(k,n). With the voiced sound detecting unit 23, noise/non-noise determining for the entire frame is performed, and when determined as non-noise, Fv(k)=1 holds, and when determined as noise, Fv(k)=0 holds. Now, the determination of the noise/non-noise with the voiced sound detecting unit 23 is performed by the zero cross width being detected based on the framing signal yf(k,n) and a histogram of this zero cross width being calculated.

The voiced sound flag Fv(k) obtained with the voiced sound detecting unit 23 for each frame is supplied to the noise/non-noise determining unit 27. Also, the band power B(k,b) of each band for each frame computed with the band power computing unit 22 is supplied to the noise/non-noise determining unit 27. With the noise/non-noise determining unit 27, the noise band flag Fnz(k,b) of each band are set for each frame, using the voiced sound flag Fv(k) and the band power B(k,b) of each band (see FIG. 5). In this case, when the voiced sound flag Fv(k) is 1 and the overall frame is determined to be non-noise, all of the bands are determined not to be noise, and Fnz(k,b)=0 holds for all of the bands.

Also, when the voiced sound flag Fv(k) is 0 and the overall frame is determined to be noise, determination of noise or non-noise is performed by stationarity detection of the band power for each band. When the band power has stationarity and the band thereof is determined to be a noise candidate, the count of the noise candidate frame continuous counter Cn(b) of the band thereof is increased by 1. Also, when the count value thereof exceeds a threshold value Tc, the band thereof is determined to be noise, and Fnz(k,b)=1 holds.

On the other hand, when the band power has no stationarity and the band thereof is determined to be non-noise, Fnz(k,b)=0 holds. Also, even if the band thereof is determined to be a noise candidate, with stationarity in the band, when the count value of the noise candidate frame continuous counter Cn(b) is at or below the threshold value Tc, the band thereof is determined to be non-noise, and Fnz(k,b)=0 holds.

The noise band flag Fnz(k,b) of each band set for each frame with the noise/non-noise determining unit 27 is supplied to the noise band power estimating unit 28. Also, the band power B(k,b) of each band calculated for each frame with the band power computing unit 22 is supplied to the noise band power estimating unit 28. With the noise band power estimating unit 28, a noise band power estimating value D(k,b) of each band is estimated for each frame.

With the noise band power estimating unit 28, updating of the noise band power estimating value D(k,b) is performed for bands wherein Fnz(k,b)=1 holds, i.e. noise bands only, based on the noise band flag Fnz(k,b). For example, band power B(k,b) is used, and updates are made using exponential weighting μnz (see Expression (10)). The value of μnz is set between approximately 0.9 and 1.0, so that the noise band power estimating value D(k,b) follows the actual noise changes, and so there is no acoustic unpleasantness.

The noise band power estimating value D(k,b) of each band estimated with the noise band power estimating unit 28 for each frame is supplied to the a posteriori SNR computing unit 29. Also, the band power B(k,b) of each band computed with the band power computing unit 22 is supplied to the a posteriori SNR computing unit 29 for each frame. With the a posteriori SNR computing unit 29, for each frame, the band power B(k,b) and the estimation value D(k,b) of the noise band power are used to compute the a posteriori SNR “γ(k,b)” fir each band (see Expression (11)).

The noise band flags Fnz(k,b) of each band set with the noise/non-noise determining unit 27 for each frame is supplied to the α computing unit 30. With the α computing unit 30, a weighted coefficient α(k,b) for computing the a priori SNR “ξ(k,b)” of each band (see Expression (14)) is computed for each frame. The weighted coefficient α(k,b) is updated so as to near the maximum value αMAX(b) for a band b determined to be noise, and immediately as the minimum value αMIN(b) for a band b determined to be non-noise (see Expression (13) and FIG. 6).

The a posteriori SNR “γ(k,b)” of each band computed with the a posteriori computing unit 29 for each frame is supplied to the a priori SNR computing unit 31. Also, the weighted coefficient α(k,b) of each band computed with the α computing unit 30 for each frame is supplied to the before-the-face SNR computing unit 31. Further, the noise suppression gain G′(k,b) of each band of the immediately preceding frame corrected with the noise suppression gain correcting unit 33 is supplied to the a priori SNR computing unit 31. With the a priori SNR computing unit 31, an a priori SNR “ξ(k,b)” of each band (see Expression (14)) is computed for each frame. In this case, the a posteriori SNR “γ(k−1,b)” of the immediately preceding frame and current frame, the noise suppression gain G′(k−1,b) of the immediately preceding frame, and the weighted coefficient α(k,b) are used.

As described above, the weighted coefficient α(k,b) of each band computed with the α computing unit 30 is updated so as to near the maximum value αMAX(b) for a band b determined to be noise, and immediately as the minimum value αMIN(b) for a band b determined to be non-noise. Therefore, the a priori SNR “ξ(k,b)” is calculated so that following is fast as to non-noise which generally has wide variances such as audio, and conversely, following is slow as to noise of which stationarity is assumed.

The a posteriori SNR “γ(k,b)” of each band computed with the a posteriori SNR computing unit 29 for each frame is supplied to the noise suppression gain computing unit 32. Also, the a priori SNR “ξ(k,b)” of each band computed with the a priori SNR computing unit 31 for each frame is supplied to the noise suppression gain computing unit 32. With the noise suppression gain computing unit 32, a noise suppression gain G(k,b) of each band is computed for each frame from the a posteriori SNR “γ(k,b)” and the a priori SNR “ξ(k,b)” (see Expression (15)).

The noise suppression gain G(k,b) of each band computed with the noise suppression gain computing unit 32 for each frame is supplied to the noise suppression gain correcting unit 33. For each frame, the noise suppression gain correcting unit 33 factors a limiter to the noise suppression gain G(k,b) of each band, based on a lower-limit value GMIN(b) of the noise suppression gain set beforehand of each band, and computes a corrected noise suppression gain G′(k,b).

The noise suppression gain G′(k,b) of each band corrected with the noise suppression gain correcting unit 33 for each frame is supplied to the filter configuring unit 34. With the filter configuring unit 34, the noise suppression gain corresponding to each Fourier coefficient is computed from the noise suppression gain G′(k,b) of each band, for each frame. The noise suppression gain corresponding to the various Fourier coefficients thus computed with the filter configuring unit 34 for each frame is supplied to the Fourier coefficient correcting unit 16 as output of the noise suppression gain generating unit 15.

As described above, in the noise suppression device 10 shown in FIG. 1, the noise suppression gain G(k,b) of each band is computed from the a posteriori SNR “γ(k,b)” and the a priori SNR “ξ(k,b)” with the noise suppression gain computing unit 32 of the noise suppression gain generating unit 15. Also, the a priori SNR “ξ(k,b)” of each band is computed with the a priori SNR computing unit 31. In this case, the a posteriori SNR “γ(k−1,b), γ(k,b)” of the immediately preceding frame and current frame, the noise suppression gain G′ (k−1,b) of the immediately preceding frame, and the weighted coefficient α(k,b).

The weighted coefficient α(k,b) of each band computed with the α computing unit 30 is changed appropriately according to the signal state. That is to say, the weighted coefficient α(k,b) is updated so as to near the maximum value αMAX(b) for a band b (Fnz(k,b)=1) determined to be noise, and immediately as the minimum value αMIN(b) for a band b (Fnz(k,b)=0) determined to be non-noise. Therefore, the a priori SNR “ξ(k,b)” is calculated so that following is fast as to non-noise which generally has wide variances such as audio, and conversely, following is slow as to noise of which stationarity is assumed.

Therefore, the precision (following) of the noise suppression gain G(k,b) of each band computed with the noise suppression gain generating unit 15 can be increased. Accordingly, for example, sound quality deterioration that occurs in locations having wide signal variances such as the beginning of an audio signal can be suppressed, musical noise can be suppressed in locations such as stationary noise segments where signal variances are mild, and sound quality can be improved.

Also, as described above, in the noise suppression device 10 shown in FIG. 1, a noise band flag Fnz(k,b) of each band is set with the noise/non-noise determining unit 27 of the noise suppression gain generating unit 15, using the voiced sound flag Fv(k) and the band power B(k,b) of each band. That is to say, even in a signal where noise and non-noise is mixed, detection can be made regarding noise of a band that does not overlap with non-noise. Also, with the noise band power estimating units 28, updating of the noise band power estimating value D(k,b) for a band only wherein Fnz(k,b)=1 holds, i.e., for a noise band, can be performed based on the noise band flag Fnz (k,b). Therefore, time following capability of the estimating of the noise band power estimating value D(k,b) can be improved, while estimating precision can be improved. Accordingly, the precision of the noise suppression gain can be improved as a result, and sound quality can be improved.

Also, as described above, in the noise suppression device 10 shown in FIG. 1, a noise band flag Fnz(k,b) of each band is set with the noise/non-noise determining unit 27 of the noise suppression gain generating unit 15, using the voiced sound flag Fv(k) and the band power B(k,b) of each band. That is to say, with the noise/non-noise determining unit 27, noise/non-noise determining with the voiced sound flag Fv(k) is performed over the entire frame, and by combining this with the determining of each band with the band power stationarity detection, a final determination result can be obtained. Accordingly, determination precision of the noise/non-noise of each band can be increased.

Also, as described above, in the noise suppression device 10 shown in FIG. 1, the corrected noise suppression gain G′(k,b) is computed with the noise suppression gain correcting unit 33 of the noise suppression gain generating unit 15. In this case, a limiter is factored to the noise suppression gain G(k,b) of each band, based on a lower-limit value GMIN(b) of the noise suppression gain set beforehand of each band, and correcting is performed. Accordingly, while the acoustic noise reduction amount is maximized, the sound quality deterioration is prevented from becoming too small as a result of estimation error or the like.

Note that in the noise suppression device 10 shown in FIG. 1, a noise band flag Fnz(k,b) of each band is set with the noise/non-noise determining unit 27 of the noise suppression gain generating unit 15, using the voiced sound flag Fv(k) and the band power B(k,b) of each band. However, with the noise/non-noise determining unit 27, setting a noise band flag Fnz(k,b) of each band, using a voiced sound flag Fv(k) or only one of the band power B(k,b) of each band, for each frame, can be considered.

In the case of setting a noise band flag Fnz(k,b) of each band using only the voiced sound flag Fv(k), determining processing of the flowchart in FIG. 5, except for the processing in step ST6, for example, is performed with the noise/non-noise determining unit 27. On the other hand, in the case of setting a noise band flag Fnz(k,b) of each band using only one of the band power B(k,b) of each band, determining processing of the flowchart in FIG. 5, except for the processing in step ST2, for example, is performed with the noise/non-noise determining unit 27.

### 2. Second Embodiment

### Noise Suppression Device

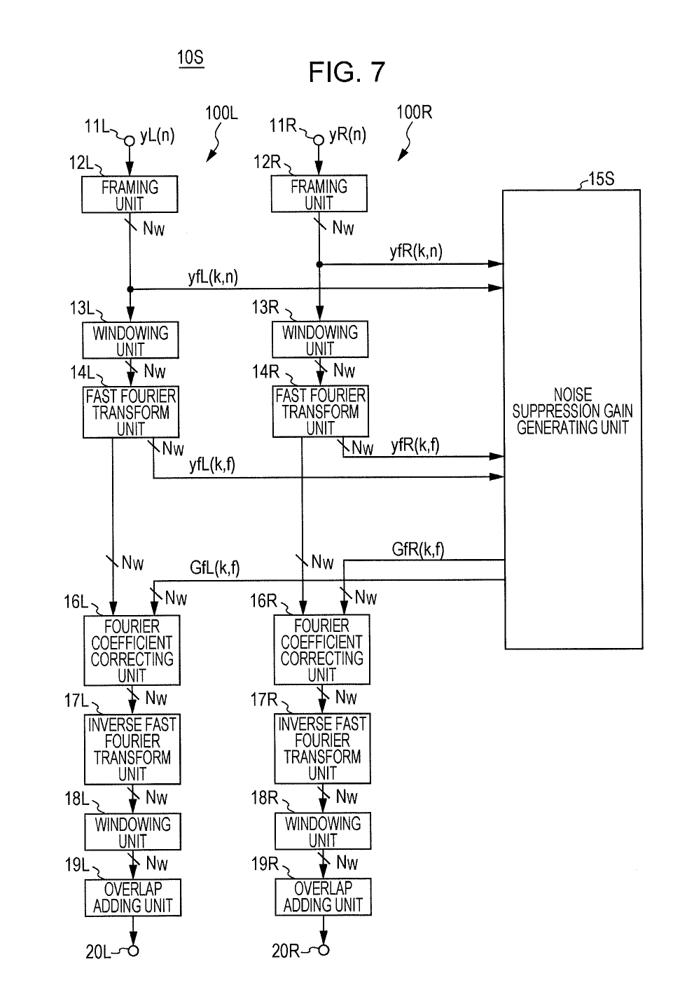

FIG. 7 shows a configuration example of a noise suppression device 10S according to a second embodiment. As compared to the noise suppression device 10 shown in FIG. 1 being a configuration example in the case of being applicable to noise suppression of a monaural signal, the noise suppression device 10S is a configuration example in the case of being applicable to noise suppression of a stereo signal. In FIG. 7, portions corresponding to FIG. 1 are appended with the same reference numeral, or the letter “L” or “R” is appended to the same reference numeral and shown, and the detailed description thereof will be omitted as appropriate. In the event of being applicable to a stereo signal, basically the processing for a monaural signal should be performed for each channel. However, in the case of a stereo signal, adverse effects can occur, such as the localization in the processing results deteriorating, resulting from estimation error or the like. Therefore, countermeasures for dealing with stereo signals are implemented.

The noise suppression device 10S is made up of a left channel (Lch) processing system 100L, a right channel (Rch) processing system 100L, and a noise suppression gain generating unit 15S. The left channel processing system 100L and right channel processing system 100L are each configured similar to the processing system of the noise suppression device 10 shown in FIG. 1, from the signal input terminal 11 through the signal output terminal 20.

That is to say, the left channel processing system 100L has a signal input terminal 11L, framing unit 12L, windowing unit 13L, and fast Fourier transform unit 14L. Also, the left channel processing system 100L has a Fourier coefficient correcting unit 16L, inverse fast Fourier transform unit 17L, windowing unit 18L, overlap adding unit 19L, and signal output terminal 20L.

Also, the right channel processing system 100R has a signal input terminal 11R, framing unit 12R, windowing unit 13R, and fast Fourier transform unit 14R. Also, the right channel processing system 100R has a Fourier coefficient correcting unit 16R, inverse fast Fourier transform unit 17R, windowing unit 18R, overlap adding unit 19R, and signal output terminal 20R.

The noise suppression gain generating unit 15S generates a noise suppression gain corresponding to the various Fourier coefficient of the left channel processing system 100L and a noise suppression gain corresponding to the various Fourier coefficient of the right channel processing system 100R for each frame. The noise suppression gain generating unit 15S generates noise suppression gains GfL(k,f) and GfR(k,f) corresponding to the various Fourier coefficients of the left channel processing system 100L and right channel processing system 100R. in this case, the noise suppression gain generating unit 15S generates noise suppression gains GfL(k,f) and GfR(k,f) for each channel, based on the framing signals and the various Fourier coefficients (various frequency spectrums). Details of the noise suppression gain generating unit 15S will be described later.

The operations of the noise suppression device 10S will be described briefly. With the left channel processing system 100L, a left channel input signal yL(n) is supplied to the signal input terminal 11L, and the input signal yL(n) is supplied to the framing unit 12L. With the framing unit 12L, the input signal yL(n) is framed in order to perform processing for each frame. That is to say, with the framing unit 12L, the input signal yL(n) is divided into predetermined frame lengths, for example frames of which the frame length is an Nf sample. The framing signal yfL(k,n) for each frame is sequentially supplied to the windowing unit 13L.

With the windowing unit 13L, in order to obtain the Fourier coefficient stabilized with the later-described fast Fourier transform unit 14L, windowing of the framing signal yfL(k,n) is performed with an analyzing window wana(n). The framing signal yfL(k,n) thus windowed is supplied to the fast Fourier transform unit 14L. With the fast Fourier transform unit 14L, the windowed framing signal yfL(k,n) is subjected to fast Fourier transform processing, and is transformed from a time region signal to a frequency region signal. The various Fourier coefficients (various frequency spectrums) YfL(k,f) obtained with the fast Fourier transform processing are supplied to the Fourier coefficient correcting unit 16L. Note that (k,f) shows the f′th frequency of the k′th frame.

Also, with the right channel processing system 100R, a right channel input signal yR(n) is supplied to the signal input terminal 11R, and the input signal yR(n) is supplied to the framing unit 12R. With the framing unit 12R, the input signal yR(n) is framed in order to perform processing for each frame. That is to say, with the framing unit 12R, the input signal yR(n) is divided into predetermined frame lengths, for example frames of which the frame length is an Nf sample. The framing signal yfR(k,n) for each frame is sequentially supplied to the windowing unit 13R.

With the windowing unit 13R, in order to obtain the Fourier coefficient stabilized with the later-described fast Fourier transform unit 14R, windowing of the framing signal yfR(k,n) is performed with an analyzing window wana(n). The framing signal yfR(k,n) thus windowed is supplied to the fast Fourier transform unit 14R. With the fast Fourier transform unit 14R, the windowed framing signal yfR(k,n) is subjected to fast Fourier transform processing, and is transformed from a time region signal to a frequency region signal. The various Fourier coefficients (various frequency spectrums) YfR(k,f) obtained with the fast Fourier transform processing are supplied to the Fourier coefficient correcting unit 16R. Note that (k,f) shows the f′th frequency of the k′th frame.

The framing signals yfL(k,n) and yfR(k,n) for each frame obtained with the framing units 12L and 12R are supplied to the noise suppression gain generating unit 15S. Also, the Fourier coefficients YfL(k,n) and YfR(k,n) for each frame obtained with the fast Fourier transform units 14L and 14R are supplied to the noise suppression gain generating unit 15S. Noise suppression gain corresponding to the various Fourier coefficients common to the left and right channels are generated with the noise suppression gain generating unit 15S, for each frame, based on the framing signals fyL(k,n) and yfR(k,n) and the Fourier coefficients YfL(k,n) and YfR(k,n).

Also, in the left channel processing system 100L, corrections to the various Fourier coefficients YfL(k,n) obtained by fast Fourier transform processing with the fast Fourier transform unit 14L is performed for each frame with the Fourier coefficient correcting unit 16L. In this case, the product of the various Fourier coefficients YfL(k,n) and the noise suppression gains GfL(k,f) corresponding to the various Fourier coefficients generated with the noise suppression gain generating unit 15S is taken and coefficient correction is performed. That is to say, filter calculations for suppressing the noise on the frequency axis is performed with the Fourier coefficient correcting unit 16L. The various Fourier coefficients subjected to coefficient corrections are supplied to the inverse fast Fourier transform unit 17L.

With the inverse fast Fourier transform unit 17L, inverse fast Fourier transform processing is performed as to the various Fourier coefficients subjected to coefficient corrections for each frame, and the frequency region signals are transformed into time region signals. The framing signals obtained with the inverse fast Fourier transform unit 17L are supplied to the windowing unit 18L. With the windowing unit 18L, windowing is performed as to the framing signals obtained with the inverse fast Fourier transform unit 17L with a synthesis window wsyn(n) for each frame.

The framing signals for each frame that have been windowed with the windowing unit 18L are supplied to the overlap adding unit 19L. With the overlap adding unit 19L, framing border portions of the framing signal for each frame are layered, and an output signal having the noise suppressed is obtained. This output signal is then output to the signal output terminal 20L of the left channel processing system 100L.

Also, in the right channel processing system 100R, corrections to the various Fourier coefficients YfR(k,n) obtained by fast Fourier transform processing with the fast Fourier transform unit 14R is performed for each frame with the Fourier coefficient correcting unit 16R. In this case, the product of the various Fourier coefficients YfR(k,n) and the noise suppression gains GfR(k,f) corresponding to the various Fourier coefficients generated with the noise suppression gain generating unit 15S is taken and coefficient correction is performed. That is to say, filter calculations for suppressing the noise on the frequency axis is performed with the Fourier coefficient correcting unit 16R. The various Fourier coefficients subjected to coefficient corrections are supplied to the inverse fast Fourier transform unit 17R.

With the inverse fast Fourier transform unit 17R, inverse fast Fourier transform processing is performed as to the various Fourier coefficients subjected to coefficient corrections for each frame, and the frequency region signals are transformed into time region signals. The framing signals obtained with the inverse fast Fourier transform unit 17R are supplied to the windowing unit 18R. With the windowing unit 18R, windowing is performed as to the framing signals obtained with the inverse fast Fourier transform unit 17R with a synthesis window wsyn(n) for each frame.

The framing signals for each frame that have been windowed with the windowing unit 18R are supplied to the overlap adding unit 19R. With the overlap adding unit 19R, framing border portions of the framing signal for each frame are layered, and an output signal having the noise suppressed is obtained. This output signal is then output to the signal output terminal 20R of the right channel processing system 100R.

### Noise Suppression Gain Generating Unit

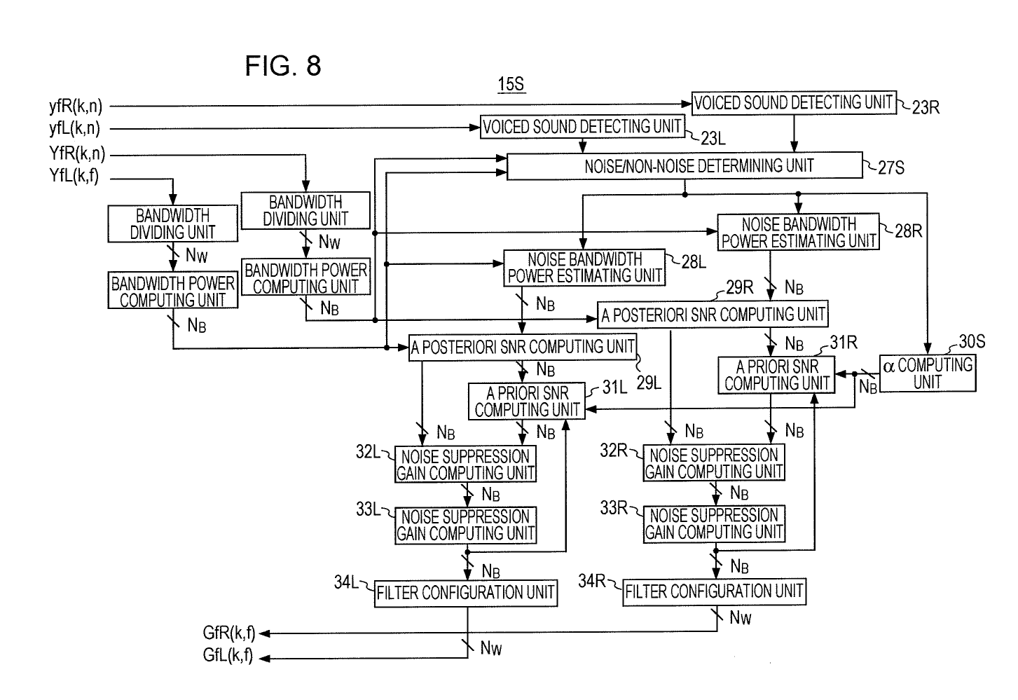

Details of the noise suppression gain generating unit 15S will be described. FIG. 8 shows a configuration example of the noise suppression gain generating unit 15S. In FIG. 8, portions corresponding to FIG. 1 are appended with the same reference numeral, or the letter “L”, “R”, or “S” is appended to the same reference numeral and shown, and the detailed description thereof will be omitted as appropriate. Now, “L” indicates the processing portion on the left channel side, “R” indicates the processing portion on the right channel side, and “S” indicates common processing portions for the left and right channels.

The noise suppression gain generating unit 15S has band dividing units 21L and 21R, band power computing units 22L and 22R, voiced sound detecting units 23L and 23R, noise/non-noise determining units 27S, and noise band power estimating units 28L and 28R. Also, the noise suppression gain generating unit 15S has a posteriori SNR computing units 29L and 29R, α computing unit 30S, a priori SNR computing units 31L and 31R, noise suppression gain computing units 32L and 32R, noise suppression gain correcting units 33L and 33R, and filter configuration units 34L and 34R.

The band dividing units 21L and 21R are configured similar to the band dividing unit 21 of the noise suppression gain generating unit 15 of the noise suppression device 10 shown in FIG. 1. The band dividing units 21L and 21R divide the various frequency spectrums (various Fourier coefficients) YfL(k,f), YfR(k,f) obtained with the fast Fourier transform units 14L and 14R into 25 frequency bands, for example (see Chart 1). The band power computing units 22L and 22R are configured similar to the band power computing unit 22 of the noise suppression gain generating unit 15 of the noise suppression device 10 shown in FIG. 1. The band power computing units 22L and 22R compute band powers BR(k,b) and BR(k,b) from the frequency spectrums of each band divided with the band dividing units 21L and 21R.

The voiced sound detecting units 23L and 23R are configured similar to the voiced sound detecting unit 23 of the noise suppression gain generating unit 15 of the noise suppression device 10 shown in FIG. 1. The voiced sound detecting units 23L and 23R output voiced sound flags FvL(k) and FvR(k) indicating whether or not a voiced sound is included in each frame, based on the framing signals yfL(k,n) and yfR(k,n) obtained with the framing units 12L and 12R.

The noise/non-noise determining unit 27S is configured approximately similar to the noise/non-noise determining unit 27 of the noise suppression gain generating unit 15 of the noise suppression device 10 shown in FIG. 1. The noise/non-noise determining unit 27S is set to handle stereo, and sets noise band flags Fnz(k,b) of each band common to the left and right channels for each frame.

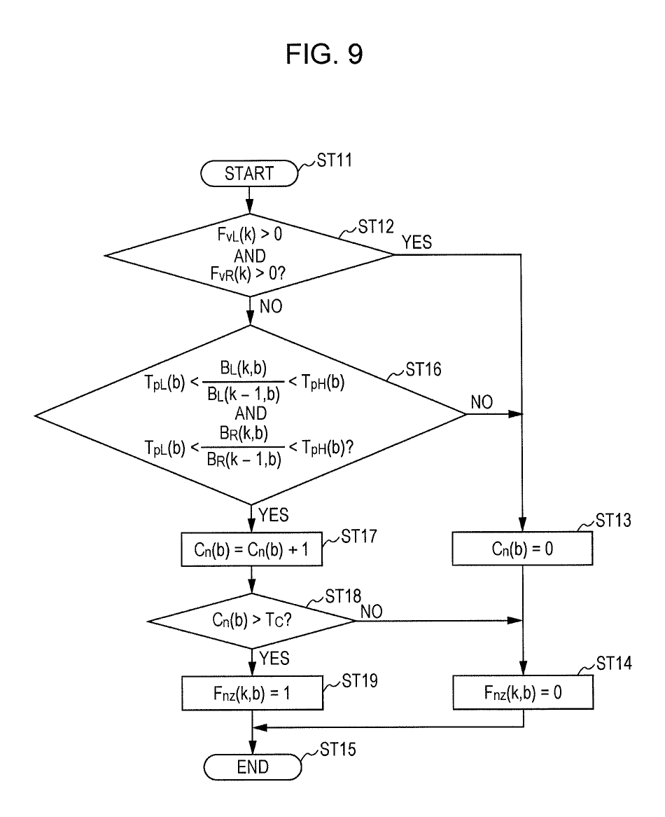

The noise/non-noise determining unit 27S sets noise band flags Fnz(k,b) of each band. In this case, the noise/non-noise determining unit 27S uses the voiced sound flags FvL(k) and FvR(k) obtained with the voiced sound detecting unit 23L and 23R, and the band powers BL(k,b) and BR(k,b) of each band computed with the band power computing units 22L and 22R. The noise/non-noise determining unit 27S executes the determining processing shown in the flowchart in FIG. 9 of each band, for each frame.

The noise/non-noise determining unit 27S starts the determining processing in step ST11, and performs system initialization. With this initialization, the noise/non-noise determining unit 27S initializes the noise candidate frame continuous counter Cn(b) to Cn(b)=0.

Next, the noise/non-noise determining unit 27S moves to the processing in step ST12. In step ST12, the noise/non-noise determining unit 27S determines whether or not the voiced sound flag FvL(k) is greater than 0, i.e., whether or not FvL(k)=1. Also, in step ST12, the noise/non-noise determining unit 27S determines whether or not the voiced sound flag FvR(k) is greater than 0, i.e., whether or not FvR(k)=1.

When FvL(k)=1 and FvR(k)=1, i.e., when the current frame k is a voiced sound on both the left and right channels, the noise/non-noise determining unit 27S clears the noise candidate frame continuous counter Cn(b) in step ST13, and sets this to Cn(b)=0. The noise/non-noise determining unit 27S when determines that the current band b is not noise, and sets the noise band flag Fnz(k,b) to Fnz(k,b)=0 in step ST14, and thereafter ends the determining processing in step ST15.

When FvL(k)=1 holds and FvR(k)=1 does not hold in step ST12, i.e., when one or the other of at least the left and right channels of the current frame k is not a voiced sound, the noise/non-noise determining unit 27S moves to the processing in step ST16. In step ST16, the noise/non-noise determining unit 27S finds the power ratio between the band power BL(k,b) of the current frame k on the left channel side and the band power BL(k−1,b) of the immediately preceding frame k−1. Also, in step ST16, the noise/non-noise determining unit 27S finds the power ratio between the band power BR(k,b) of the current frame k on the right channel side and the band power BR(k−1,b) of the immediately preceding frame k−1.

In step ST16 herein, the noise/non-noise determining unit 27S determines whether or not both power ratios of the left and right channels are contained between a low level side threshold value TpL(b) and a high level threshold value TpH(b). That is to say, determination is made as to whether or not TpL(b)<BL(k,b)/BL(k−1,b)<TpH(b) holds and TpL(b)<BR(k,b)/BR(k−1,b)<TpH(b) holds.

When both power ratios of the left and right channels are contained between thresholds, the noise/non-noise determining unit 27S set the current band b as a noise candidate, when both power ratios of the left and right channels are not contained between thresholds, determines that the current band b is not noise. The determination herein is based on an assumption that the noise signal power is fixed, and conversely that a signal having wide power variances is not noise.

When both power ratios of the left and right channels are not contained between thresholds, in step ST13 the noise/non-noise determining unit 27S clears the noise candidate frame continuous counter Cn(b) and sets this to Cn(b)=0. The noise/non-noise determining unit 27S then determines that the current band b is not noise, and in step ST14 sets Fnz(k,b)=0, and thereafter in step ST15 ends the determining processing.

On the other hand, when both power ratios of the left and right channels are contained between thresholds, i.e., when the current band b is set as a noise candidate, the noise/non-noise determining unit 27S moves to the processing in step ST17. In step ST17, the noise/non-noise determining unit 27S increases the count of the noise candidate frame continuous counter Cn(b) by 1.

The noise/non-noise determining unit 27S then determines in step ST18 whether or not the noise candidate frame continuous counter Cn(b) has exceeded a threshold value Tc. When Cn(b)>Tc does not hold, the noise/non-noise determining unit 27S determines that the current band b is not noise, and in step ST14 sets Fnz(k,b)=0, and thereafter, in step ST15 ends the determining processing.

On the other hand, when Cn(b)>Tc holds, the noise/non-noise determining unit 27S moves to the processing in step ST19. In step ST19, the noise/non-noise determining unit 27S determines that the current band b is noise, and sets the noise band flag Fnz(k,b) to Fnz(k,b)=1, and thereafter, in step ST15 ends the determining processing.

Returning to FIG. 8, the noise band power estimating units 28L and 28R are configured similar to the noise band power estimating unit 28 of the noise suppression gain generating unit 15 of the noise suppression device 10 shown in FIG. 1. The noise band power estimating units 28L and 28R estimate noise band power estimating values DL(k,b) and DR(k,b) of each band for each frame. The noise band power estimating units 28L and 28R performs updating of the noise band power estimating values DL(k,b) and DR(k,b) for the bands wherein Fnz(k,b)=1 holds, i.e., only for noise bands (see Expression (10)). In this case, the noise band power estimating units 28L and 28R perform processing based on the noise band flag Fnz(k,b) common to the left and right channels set with the noise/non-noise determining unit 27S.

The a posteriori SNR computing units 29L and 29R are configured similar to the a posteriori SNR computing unit 29 of the noise suppression gain generating unit 15 of the noise suppression device 10 shown in FIG. 1. The a posteriori SNR computing units 29L and 29R compute the a posteriori SNR “γL(k,b), γR(k,b)” of each band for each frame (see Expression (11)). In this case, the a posteriori SNR computing units 29L and 29R use the input signal band powers BL(k,b) and BR(k,b) and the noise band power estimating values DL(k,b) and DR(k,b).

The a priori SNR computing units 31L and 31R are configured similar to the a priori SNR computing unit 31 of the noise suppression gain generating unit 15 of the noise suppression device 10 shown in FIG. 1. The a priori SNR computing units 31L and 31R compute the a priori SNR “ξL(k,b), ξR(k,b)” of each band for each frame (see Expression 14)).

Now, the a priori SNR computing unit 31L computes the a priori SNR “ξL(k,b)” of each band. In this case, the a priori SNR computing unit 31L uses an a posteriori SNR “γL(k−1,b), γL(k,b)” of the immediately preceding frame and current frame, a noise suppression gain G′L(k−1,b) of the immediately preceding frame, and a weighted coefficient α(k,b) common to the left and right channels. Also, the a priori SNR computing unit 31R computes the a priori SNR “ξR(k,b)” of each band. In this case, the a priori SNR computing unit 31R uses an a posteriori SNR “γR(k−1,b), γR(k,b)” of the immediately preceding frame and current frame, a noise suppression gain G′R(k−1,b) of the immediately preceding frame, and a weighted coefficient α(k,b) common to the left and right channels.

The α computing unit 30S is configured similar to the α computing unit 30 of the noise suppression device 10 shown in FIG. 1, and computes the weighted coefficient α(k,b) common to the left and right channels used with the a priori SNR computing units 31L and 31R. The α computing unit 30S is not a fixed value, but rather is computed as a weighted coefficient α(k,b) which varies by frame and band (see Expression (13)). For a band b (Fnz(k,b)=1) determined to be noise, the weighted coefficient α(k,b) nears the maximum value αMAX(b), and for a band b (Fnz(k,b)=0) determined to be non-noise, becomes the minimum value αMIN(b).

The noise suppression gain computing units 32L and 32R are configured similar to the noise suppression gain computing unit 32 of the noise suppression gain generating unit 15 of the noise suppression device 10 shown in FIG. 1. The noise suppression gain computing units 32L and 32R compute noise suppression gains GL(k,b) and GR(k,b) of each band for each frame (see Expression (15)). In this case, the noise suppression gain computing units 32L and 32R compute the noise suppression gains GL(k,b) and GR(k,b) of each band from the a posteriori SNR “γL(k,b), γR(k,b)” and the a priori SNR “ξL(k,b), ξR(k,b)”.

The noise suppression gain correcting units 33L and 33R are configured similar to the noise suppression gain correcting unit 33 of the noise suppression gain generating unit 15 of the noise suppression device 10 shown in FIG. 1. The noise suppression gain correcting units 33L and 33R perform corrections to the noise suppression gains GL(k,b) and GR(k,b) computed with the noise suppression gain computing units 32L and 32R for each frame. That is to say, noise suppression gain correcting units 33L and 33R compute the corrected noise suppression gains G′L(k,b) and G′R(k,b) (see Expression (16)). In this case, the noise suppression gain correcting units 33L and 33R factor a limiter to the noise suppression gains GL(k,b) and GR(k,b), based on the lower limit value GMIN(b) of the noise suppression gains set beforehand of each band.

The filter configuration units 34L and 34R are configured similar to the filter configuration unit 34 of the noise suppression gain generating unit 15 of the noise suppression device 10 shown in FIG. 1. The filter configuration units 34L and 34R compute noise suppression gains GfL(k,f) and GfR(k,f) corresponding to the various Fourier coefficients from the noise suppression gains G′L(k,b) and G′R(k,b) of each band corrected with the noise suppression gain correcting unit 33 for each frame. In this case, the filter configuration units 34L and 34R make up the filter on the frequency axis.

The operations of the noise suppression gain generating unit 15S will be described briefly. The various frequency spectrums (various Fourier coefficients) YfL(k,f) and YfR(k,f) obtained by fast Fourier processing for each frame with the fast Fourier transform units 14L and 14R are supplied to the band dividing units 21L and 21R. With the band dividing units 21L and 21R herein, the various frequency spectrums YfL(k,f) and YfR(k,f) are divided into 25 frequency bands, for example, for each frame (see Chart 1).

The frequency spectrums of each band obtained by band division with the band dividing unit 21L and 21R are supplied to the band power computing units 22L and 22R for each frame. The band powers BL(k,b) and BR(k,b) of each band are computed for each frame with the band power computing units 22L and 22R. For example, the power spectrum corresponding to the various frequency spectrums within the band b are each computed, and the maximum value or average value thereof is set as the band power BL(k,b) and BR(k,b).

Also, the framing signals yfL(k,n) and yfR(k,n) obtained with the framing units 12L and 12R are supplied to the voiced sound detecting units 23L and 23R. With the voiced sound detecting units 23L and 23R, voiced sound flags FvL(k) and FvR(k), indicating whether or not a voiced sound is included for each frame, are obtained, based on the framing signals yfL(k,n) and yfR(k,n). Noise/non-noise determining of the entire frame is performed with the voiced sound detecting units 23L and 23R, and when determining as non-noise, sets FvL(k), FvR(k)=1, and when determining as noise, sets FvL(k), FvR(k)=0. Now, the noise/non-noise determining with the voiced sound detecting units 23L and 23R is performed by the zero cross width being detected based on the framing signals yfL(k,n) and yfR(k,n), and by a histogram of the zero cross width herein being calculated.

The voiced sound flags FvL(k) and FvR(k) for each frame obtained with the voiced sound detecting units 23L and 23R are supplied to the noise/non-noise determining unit 27S. Also, the band power BL(k,b) and BR(k,b) of each band computed with the band power computing unit 22L and 22R for each frame are supplied to the noise/non-noise determining unit 27S. The noise band flags Fnz(k,b) of each band common to the left and right channels are set with the noise/non-noise determining unit 27S for each frame, using the voiced sound flags FvL(k) and FvR(k) and the band powers BL(k,b) and BR(k,b) of each band (see FIG. 9).

In this case, when FvL(k)=1 and FvR(k)=1 hold, and the entire frame is determined to be non-noise with both the left and right channels, all of the bands are determined to not be noise, and Fnz(k,b)=0 holds for all bands.

Also, when FvL(k)=1 and FvR(k)=1 do not hold, and the entire frame is not determined to be non-noise with both the left and right channels, determination of noise or non-noise is performed with the stationarity detecting of the band power of each band. When the band power has stationarity with both the left and right channels, and the band thereof is determined to be a noise candidate, the count of the noise candidate frame continuous counter Cn(b) of the band thereof is increased. When the count value thereof exceeds a threshold value Tc, the band thereof is determined to be noise, and Fnz(k,b)=1 holds.

On the other hand, when the band power has no stationarity in both or one of the left and right channels, and the band is determined to be non-noise, Fnz(k,b)=0. Also, even if the band power has stationarity in both the left and right channels, and the band thereof is determined to be a noise candidate, when the count value of the noise candidate frame continuous counter Cn(b) is at or below the threshold value Tc, the band thereof is determined to be non-noise, and Fnz(k,b)=0 holds.

The noise band flags Fnz(k,b) of each band that are common to the left and right channels set by the noise/non-noise determining unit 27S for each frame are supplied to the α computing unit 30S. With this a computing unit 30S, weighted coefficients α(k,b) common to both left and right channels, for computing the a priori SNR “ξL(k,b), ξR(k,b)” of each band are computed for each frame (see Expression (13)). In this case, the weighted coefficient α(k,b) is updated so as to near the maximum value αMAX(b) for a band b determined to be noise (Fnz(k,b)=1), and immediately as the minimum value αMIN(b) for a band b determined to be non-noise (Fnz(k,b)=0).

The noise band flags Fnz(k,b) of each band common to the left and right channels set with the noise/non-noise determining unit 27S for each frame are supplied to the noise band power estimating units 28L and 28R. Also, the band powers BL(k,b) and BR(k,b) of each band computed with the band power computing units 22L and 22R for each frame are supplied to the noise band power estimating units 28L and 28R. With the noise band power estimating units 28L and 28R, the noise band power estimating values DL(k,b) and DR(k,b) of each band are estimated for each frame.

With the noise band power estimating units 28L and 28R, updating of the noise band power estimating values DL(k,b) and DR(k,b) is performed for bands wherein Fnz(k,b)=1 holds, i.e. noise bands only, based on the noise band flag Fnz(k,b). For example, band powers BL(k,b) and BR(k,b) are used, and updates are made using exponential weighting μnz (see Expression (10)). The value of μnz is set between approximately 0.9 and 1.0, so that the noise band power estimating values DL(k,b) and DR(k,b) follow the actual noise changes, and so there is no acoustic unpleasantness.

The noise band power estimating values DL(k,b) and DR(k,b) of each band estimated with the noise band power estimating units 28L and 28R for each frame are supplied to the a posteriori SNR computing units 29L and 29R. Also, the band powers BL(k,b) and BR(k,b) of each band computed with the band power computing units 22L and 22R for each frame are supplied to the a posteriori SNR computing units 29L and 29R. With the a posteriori SNR computing units 29L and 29R, the band powers BL(k,b) and BR(k,b) and the estimation values DL(k,b) and DR(k,b) of the noise band power are used to compute the a posteriori SNR “γL(k,b), γR(k,b)” of each band for each frame (see Expression (11)). In this case, the band powers BL(k,b) and BR(k,b) and estimation values DL(k,b) and DR(k,b) of the noise band power are used.

The a posteriori SNR “γL(k,b), γR(k,b)” of each band computed with the a posteriori SNR computing units 29L and 29R for each frame is supplied to the a priori SNR computing units 31L and 31R. Also, the weighted coefficient α(k,b) of each band common to both the left and right channels computed with the α computing unit 30S for each frame is supplied to the a priori SNR computing units 31L and 31R. Further, the noise suppression gains G′R(k,b) and G′R(k,b) of each band of the immediately preceding frame corrected with the noise suppression gain correcting units 23L and 23R are supplied to the a priori SNR computing units 31L and 31R.

With the a priori SNR computing units 31L and 31R, an a priori SNR “ξL(k,b), ξR(k,b)” of each band (see Expression (14)) is computed. With the a priori SNR computing unit 31L, an a priori SNR “ξL(k,b)” of each band is computed for each frame. In this case, the a posteriori SNR “γL(k−1,b), γL(k,b)” of the immediately preceding frame and current frame, the noise suppression gain G′L(k−1,b) of the immediately preceding frame, and the weighted coefficient α(k,b) are used. Also, with the a priori SNR computing unit 31R, an a priori SNR “ξR(k,b)” of each band is computed. In this case, for each frame, the a posteriori SNR “γR(k−1,b), γR(k,b)” of the immediately preceding frame and current frame, the noise suppression gain G′R(k−1,b) of the immediately preceding frame, and the weighted coefficient α(k,b) are used.

As described above, the weighted coefficient α(k,b) of each band common to the left and right channels is updated so as to near the maximum value αMAX(b) for a band b determined to be noise, and immediately as the minimum value αMIN(b) for a band b determined to be non-noise. Therefore, the a priori SNR “ξL(k,b), ξR(k,b)” is calculated so that following is fast as to non-noise which generally has wide variances such as audio, and conversely, following is slow as to noise of which stationarity is assumed.

The a posteriori SNR “γR(k,b), γR(k,b)” of each band computed with the a posteriori computing units 29L and 29R for each frame is supplied to the noise suppression gain computing units 32L and 32R. Also, the a priori SNR “ξL(k,b), ξR(k,b)” of each band computed with the a priori SNR computing units 31L and 31R for each frame is supplied to the noise suppression gain computing units 32L and 32R. With the noise suppression gain computing units 32L and 32R, noise suppression gains GL(k,b) and GR(k,b) of each band are computed for each frame from the a posteriori SNR “γL(k,b), γR(k,b)” and the a priori SNR “ξL(k,b), ξR(k,b)” (see Expression (15)).

The noise suppression gains GL(k,b) and GR(k,b) of each band computed with the noise suppression gain computing units 32L and 32R for each frame are supplied to the noise suppression gain correcting units 33L and 33R. The corrected noise suppression gains G′L(k,b) and G′R(k,b) are computed with the noise suppression gain correcting units 33L and 33R for each frame. In this case, a limiter is factored to the noise suppression gains GL(k,b) and GR(k,b) of each band, based on a lower-limit value GMIN(b) of the noise suppression gain set beforehand of each band.

The noise suppression gains G′L(k,b) and G′R(k,b) of each band corrected with the noise suppression gain correcting units 33L and 33R for each frame are supplied to the filter configuring units 34L and 34R. With the filter configuring units 34L and 34R, the noise suppression gains GfL(k,f) and GfR(k,f) corresponding to each Fourier coefficient are computed from the noise suppression gains G′L(k,b) and G′R(k,b) of each band, for each frame. The noise suppression gains corresponding to the various Fourier coefficients thus computed with the filter configuring units 34L and 34R for each frame are supplied to the Fourier coefficient correcting units 16L and 16R as output of the noise suppression gain generating unit 15S.

As described above, the noise suppression device 10S shown in FIG. 7 is a configuration example in the case of being applied to a stereo signal, but the noise suppression gain generating unit 15S is basically configured similar to the noise suppression gain generating unit 15 of the noise suppression device 10 shown in FIG. 1. Accordingly, with the noise suppression device 10S shown in FIG. 7 also, similar advantages can be obtained as with the noise suppression device 10 shown in FIG. 1.

Also, in the noise suppression device 10S shown in FIG. 7, noise band flags Fnz(k,b) of each band common to the left and right channels are set with the noise/non-noise determining unit 27S of the noise suppression gain generating unit 15S for each frame. In this case, the voiced sound flags FvL(k) and FvR(k), and the band power BL(k,b) and BR(k,b) of each band, are used. With the noise band power estimating units 28L and 28R, for each frame, noise band flags Fnz(k,b) of each band common to the left and right channels set with the noise/non-noise determining unit 27S are used, and the noise band power estimating values DL(k,b) and DR(k,b) of each band is estimated.

Thus, the noise/non-noise determination is caused to be common for the left and right channels, and a common determination result is used with the noise band power estimating units 28L and 28R. Accordingly, with the noise suppression device 10S shown in FIG. 7, the noise suppression gains GL(k,b) and GR(k,b) can be suppressed from unintended amplitude difference occurring from the estimation error of the noise band power estimating values DL(k,b) and DR(k,b) of the left and right channels. Thus, a deterioration in localization due to inconsistency in the left and right channels can be avoided.

Note that the noise suppression device 10S shown in FIG. 7 is a configuration example in the case of being applied to noise suppression of a stereo signal. While detailed description will be omitted, it goes without saying that a noise suppression device applied to noise suppression of multi-channel signals of three or more channels may be similarly configured, with common determinations of noise/non-noise for each channel.

### 3. Modification

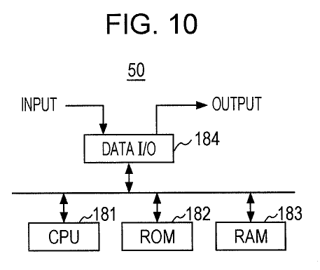

Note that the noise suppression devices 10 and 10S according to the above-described embodiments can be configured with hardware, but similar processing can also be performed with software. FIG. 10 shows a configuration example of a computer device 50 to perform the processing with software. The computer device 50 is made up of a CPU 181, ROM 182, RAM 183, and data input/output unit (data I/O) 184.

A processing program for the CPU 181 and other data are stored in the ROM 182. The RAM 183 functions as a work area of the CPU 181. The CPU 181 reads out the processing program stored in the ROM 182 as appropriate, transfers and loads the read-out processing programs to the RAM 183, reads out the loaded processing program, and executes the noise suppression processing.

With the computer device 50, an input signal (monaural signal, stereo signal) is input via the data I/O 184, and accumulated in the RAM 183. Noise suppression processing similar to the above-described embodiments is performed with the CPU 181 as to the input signal accumulated in the RAM 183. The output signal of which noise is suppressed as a processing result is output externally via the data I/O 184.

The present disclosure contains subject matter related to that disclosed in Japanese Priority Patent Application JP 2010-199512 filed in the Japan Patent Office on Sep. 7, 2010, the entire contents of which are hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A noise suppression device comprising:
a framing unit configured to divide an input signal into frames of a predetermined frame length, and frames;
a band dividing unit configured to divide the framing signal obtained with said framing unit into a plurality of bands and obtains a band divided signal;
a band power computing unit configured to obtain band power from each band divided signal obtained with said band dividing unit;
a noise determining unit configured to determine whether or not each band is noise, based on features of said framing signal;
a noise band power estimating unit configured to estimate the noise band power of various bands from the determination results of said noise determining unit and band power of each band divided signals obtained with said band power computing unit;
a noise suppression gain determining unit configured to determine noise suppression gains for each band, based on the noise band power of each band estimated with said noise band power estimating units and the band power of each band divided signals obtained with said band power computing unit;
a noise suppression unit configured to apply the noise suppression gains of each band determined with said noise suppression gain determining unit to each band divided signals obtained with said band dividing unit, and obtain a band divided signal of which noise has been suppressed;
a band synthesizing unit configured to synthesize the bands of each band divided signals obtained with said noise suppression unit, and obtain a framing signal of which noise has been suppressed; and
a framing synthesizing unit configured to synthesize the frames of the framing signals of each frames obtained with said band synthesizing unit and obtain an output signal of which noise has been suppressed;
said noise suppression gain determining unit having
an SNR computing unit configured to compute an SNR from band power of each band divided signals obtained with said band power computing unit and the noise band power of each band estimated with said noise band power estimating unit, for each band, and
a SNR smoothing unit configured to smooth the SNR computed with said SNR computing unit, for each band;
wherein the noise suppression gains for each band are determined based on the SNR of each band smoothed by said SNR smoothing unit;
and wherein said SNR smoothing unit changes the smoothing coefficient based on the determining results of said noise determining unit and frequency bands.

2. The noise suppression device according to claim 1, wherein said noise suppression gain determining unit determines the noise suppression gains of each band, based on the SNR of each band smoothed with said SNR smoothing unit and the SNR computed with said SNR computing unit.

3. The noise suppression device according to claim 1, wherein said noise suppression gain determining unit sets the ratio of the band power of a current frame signal and said estimated noise band power as a first SNR, sets the ratio of an amount wherein the band power of the immediately preceding frame signal and the noise suppression gain are multiplied, and the estimated noise band power of the immediately preceding frame, as a second SNR, and determines, for each frame, a noise suppression gain using said first SNR and said second SNR.

4. The noise suppression device according to claim 1, wherein said noise determining unit sets each band as determining band, compares the band power of the current frame and past frames of the band division signal of the determining band, and determines the determining band to be noise when variance within the band power is within a threshold.

5. The noise suppression device according to claim 1, further comprising:
a histogram computing unit configured to compute a histogram of a zero cross width in a framing signal obtained with said framing signal;
wherein said noise determining unit determines whether or not each band is noise, based on the histogram computed with said histogram computing unit.

6. The noise suppression device according to claim 1, further comprising:
a histogram computing unit configured to compute a histogram of a zero cross width in a framing signal obtained with said framing signal;
wherein said noise determining unit determines, in the case of a noise determination based on the histogram computed with said histogram computing unit, and when the variance between the current frame and past frame of the band division signal of the determining band is within a threshold, the determining band as noise, with each band as sequential determining bands.

7. The noise suppression device according to claim 1, further comprising:
a noise suppression gain correcting unit, when the noise suppression gain determined with said noise suppression gain determining unit is smaller than a lower limit value set beforehand, configured to correct the value of the noise suppression gain to the lower limit value; wherein
said noise suppression unit uses the noise suppression gain corrected with said noise suppression gain correcting unit.

8. A noise suppression device comprising:
a plurality of framing units configured to divide input signals of a plurality of channels into frames of a predetermined frame lengths, respectively, and frame;
a plurality of band dividing units configured to divide the framing signals obtained with said plurality of framing units into a plurality of bands, respectively, and obtain band divided signals;
a plurality of band power computing units configured to obtain band power from each band division signals obtained with said plurality of band dividing units, respectively;
a noise determining unit configured to determine whether or not each band is noise, based on features of said framing signals of said plurality of channels;
a plurality of noise band power estimating units configured to estimate the noise band power of various bands from the determination results of said noise determining unit and band power of each band divided signals obtained with said plurality of band power computing units;
a plurality of noise suppression gain determining units configured to determine noise suppression gains for each band, based on the noise band power of each band estimated with said plurality of noise band power estimating units and the band power of each band divided signals obtained with said plurality of band power computing units;
a plurality of noise suppression units configured to apply the noise suppression gains of each band determined with said plurality of noise suppression gain determining units to each band divided signals obtained with said plurality of band dividing units, and obtains band divided signals of which noise have been suppressed, respectively;
a plurality of band synthesizing units configured to synthesize the bands of each band divided signals obtained with said plurality of noise suppression units, and obtain framing signals of which noise have been suppressed, respectively; and
a plurality of framing synthesizing units configured to synthesize the frames of the framing signals of each frames obtained with said plurality of band synthesizing units and obtain output signals of which noise have been suppressed, respectively;
said noise suppression gain determining unit having
an SNR computing unit configured to compute an SNR from band power of each band divided signals obtained with said band power computing unit and the noise band power of each band estimated with said noise band power estimating unit, for each band, and
a SNR smoothing unit configured to smooth the SNR computed with said SNR computing unit, for each band;
wherein the noise suppression gains for each band are determined based on the SNR of each band smoothed by said SNR smoothing unit;
and wherein said SNR smoothing unit changes the smoothing coefficient based on the determining results of said noise determining unit and frequency bands.

9. The noise suppression device according to claim 8, wherein said noise determining unit sets each band as sequential determining bands, determines for each determining band whether or not each channel is noise, and when determining as noise for all channels, determines that the determining band is noise.

10. A noise suppression method, comprising:
framing to divide an input signal into frames of predetermined frame lengths and frame;
band dividing to divide the framing signal obtained by said framing into a plurality of bands and obtains a band divided signal;
band power computing to obtain band power from each band divided signal obtained by said band dividing;
noise determining to determine whether or not each band is noise, based on features of said framing signal;
noise band power estimating to estimate the noise band power of each band from the determination results of said noise determining and band power of each band divided signal obtained by said band power computing;
noise suppression gain determining to determine noise suppression gains for each band, based on the noise band power of each band estimated by said noise band power estimating and the band power of each band divided signal obtained by said band power computing;
noise suppression to apply the noise suppression gains of each band determined by said noise suppression gain determining to each band divided signal obtained by said band dividing, and obtain a band divided signal of which noise has been suppressed;
band synthesizing to synthesize the bands of each band divided signal obtained by said noise suppression, and obtain a framing signal of which noise has been suppressed; and
framing synthesizing to synthesize the frames of the framing signals of each frame obtained by said band synthesizing and obtain an output signal of which noise has been suppressed; wherein
wherein with said noise suppression gain determining, for each band, an SNR is computed from the band power of the band divided signal obtained by said band power computing and the noise band power of the band estimated by said noise band power estimating, said computed SNR is smoothed, noise suppression gain is determined based on the smoothed SNR, and smoothing coefficients are changed based on the determination results of said noise determining and frequency band.

11. A program to cause a computer to function as:
a framing unit configured to divide an input signal into frames of predetermined frame length, and frame;
a band dividing unit configured to divide the framing signal obtained by said framing unit into a plurality of bands and obtain a band divided signal;
a band power computing unit configured to obtain band power from each band divided signal obtained with said band dividing unit;
a noise determining unit configured to determine whether or not each band is noise, based on features of said framing signal;
a noise band power estimating unit configured to estimate the noise band power of each band from the determination results of said noise determining unit and band power of each band divided signal obtained with said band power computing unit;
a noise suppression gain determining unit configured to determine noise suppression gains for each band, based on the noise band power of each band estimated with said noise band power estimating unit and the band power of each band divided signal obtained with said band power computing unit;
a noise suppression unit configured to apply the noise suppression gains of each band determined with said noise suppression gain determining unit to each band divided signal obtained with said band dividing unit, and obtain a band divided signal of which noise has been suppressed;
a band synthesizing unit configured to synthesize the bands of each band divided signal obtained with said noise suppression unit, and obtain a framing signal of which noise has been suppressed; and
a framing synthesizing unit configured to synthesize the frames of the framing signals of each frame obtained with said band synthesizing unit and obtain an output signal of which noise has been suppressed; wherein
said noise suppression gain determining unit having
a SNR computing unit configured to compute an SNR from band power of each band divided signal obtained with said band power computing unit and the noise band power of each band estimated with said noise band power estimating unit, for each band, and
a SNR smoothing unit configured to smooth the SNR computed with said SNR computing unit for each band;
wherein the noise suppression gains for each band are determined based on the SNR of each band smoothed by said SNR smoothing unit;
and wherein said SNR smoothing unit changes the smoothing coefficient based on the determination results of said noise determining unit and frequency bands.
